(19) United States
(12) Patent Application Publication
(10) Pub. No.: US 2025/0234634 A1
(43) Pub. Date: Jul. 17, 2025

(54) BIPOLAR JUNCTION TRANSISTOR WITH DIELECTRIC ISOLATION STRUCTURES

(71) Applicant: TAIWAN SEMICONDUCTOR MANUFACTURING COMPANY, LTD., Hsinchu (TW)

(72) Inventors: Ming-Shuan LI, Hsinchu (TW); Chih Chieh YEH, Taipei (TW); Zi-Ang SU, Taoyuan (TW)

(21) Appl. No.: 18/734,328

(22) Filed: Jun. 5, 2024

Related U.S. Application Data
(60) Provisional application No. 63/620,309, filed on Jan. 12, 2024.

(51) Int. Cl. H01L 29/73; H01L 21/762; H01L 27/06; H01L 29/06; H01L 29/423; H01L 29/66; H01L 29/732; H01L 29/775; H01L 29/786

(52) U.S. Cl. CPC H10D 84/121; H01L 21/76224; H10D 10/052; H10D 10/461; H10D 30/014; H10D 30/43; H10D 30/6735; H10D 30/6757; H10D 62/121; H10D 84/401

(57) ABSTRACT

Embodiments provide bipolar junction transistors (BJTs) which are formed from GAA or FinFET transistors and methods of forming the BJTs. The BJTs include dielectric isolation structures formed between gates of the GAA or FinFET transistors. The dielectric isolation structures reduce spacing between transistors of neighboring terminals of the BJTs. The dielectric isolation structures allow the BJTs to use the nominal gate spacing (Lg) as logic device, thereby, compatible with the GAA or FinFET processes.

### CROSS-REFERENCE TO RELATED APPLICATIONS

This application claims priority to United States Provisional Patent Application Ser. No. 63/620,309 filed Jan. 12, 2024, which is incorporated by reference in its entirety.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

A bipolar junction transistor (BJT) includes a base, a collector, and an emitter. BJTs are formed by two p-n junctions placed back-to-back, with one of the regions common to both junctions. This arrangement forms either a PNP or NPN bipolar junction transistor. In BJTs, the current flow through the emitter and collector is controlled by the voltage across the base and emitter. As the semiconductor industry has progressed into nanometer technology process nodes in pursuit of higher device density, higher performance, and lower costs, various techniques have been implemented to improve BJT device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a plan view of a bipolar junction transistor device according to embodiments of the present disclosure.

FIG. 2 is a schematic partial perspective view of a bipolar junction transistor device in accordance with some embodiments.

FIGS. 2A-2E are schematic cross-sectional views of the bipolar junction transistor device of FIG. 2.

FIG. 3 is a flow chart of a method for forming a bipolar junction transistor device according to embodiments of the present disclosure.

FIGS. 4-10, 10A-10C, 11, 11A-11C, 12, 12A-12C, 13, 13A-13C, 14, 14A-14C, 15, 15A-15C, and 16A-16C illustrate various views of intermediate stages in the manufacturing of a bipolar junction transistor, in accordance with some embodiments.

FIGS. 17, 18, 18A-18C, and 19A-19C illustrate a bipolar junction transistor device in accordance with some embodiments.

FIGS. 20 and 21A-21C illustrate a bipolar junction transistor device in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. In the present disclosure, a source/drain region refers to a source and/or a drain. A source and a drain are interchangeably used.

Embodiments provide BJTs which are formed from GAA or FinFET transistors and methods of forming the BJTs. In some embodiments, the BJTs include dielectric isolation structures formed between gates of the GAA or FinFET transistors. The dielectric isolation structures may be formed using a cut metal gate process, which may be performed to fabricate the GAA or FinFET transistors. The BJTs according to the present disclosure may be formed using GAA or FinFET processes, therefore, may be formed with logic devices during the same processes. The dielectric isolation structures reduce spacing between transistors of neighboring terminals of the BJTs. The dielectric isolation structures allow the BJTs to use the nominal gate spacing (Lg) as logic device, thereby, compatible with the GAA or FinFET processes.

In some embodiments, a BJT includes a series of p-type GAA/FinFET transistors tied together to form a BJT collector terminal, a series of n-type GAA/FinFET transistors tied together to from a BJT base terminal, and a series of p-type GAA/FinFET transistors tied together to from a BJT emitter terminal. The source/drain regions of each of these series of GAA/FinFET transistors may be electrically coupled together, which may also be electrically coupled to the gate electrodes of the GAA/FinFET transistors. When put in appropriate contact to each other through the substrate, a lateral BJT transistor is formed. For example, in this case, the BJT transistor is a PNP BJT transistor. Alternatively, the BJT according to the present disclosure may be a NPN BJT, including a series of n-type GAA/FinFET transistors tied together to form a BJT collector terminal, a series of p-type GAA/FinFET transistors tied together to from a BJT base terminal, and a series of n-type GAA/FinFET transistors tied together to from a BJT emitter terminal.

The gate structures of the GAA/FinFET transistors may include metal gate structures formed in the same process of GAA/FinFET transistors in the logic devices. The gate structures may span across the terminals with dielectric isolation structures formed between certain terminals. For example, dielectric isolation structures are formed between in the gate structures between the collector terminal and the base terminal.

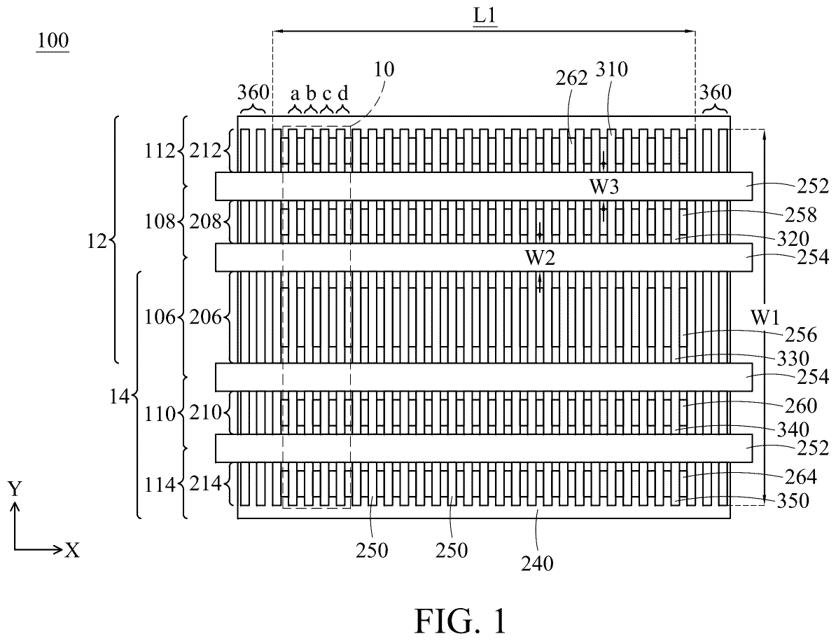

FIG. 1 is a schematic top view of a semiconductor device 100 after an intermediate stage in fabrication, in accordance with some embodiments.

Particularly, the semiconductor device 100 includes two lateral BJTs 12 and 14. The BJT 12 includes an emitter terminal 106, a base terminal 108, and a collector terminal 112 and the BJT 14 includes the emitter terminal 106, a base terminal 110, and collector terminal 114. In FIG. 1, an active area of the semiconductor device 100 is defined by length L1 and width W1. An overall length L1 of the BJTs 12, 14 m may be between about 1 μm and about 5 μm. The width W1 may be between about 1.0 μm and 3.5 μm.

In some embodiments, the BJT 12 and BJT 14 in the semiconductor device 100 may function as two separate BJTs, which share a common emitter terminal 106. In some embodiments, the BJTs 12 and 14 can effectively act as a single BJTs. For example, the base terminal 108 of the BJT 12 and the base terminal 110 of BJT 14 may be coupled together in a metallization layer, and the collector terminal 112 of BJT 12 and collector terminal 114 of BJT 14 may be coupled together in a metallization layer. The BJT 12 and BJT 14 are tied together and effectively act as a single BJT having a length of about 2×L1.

Each terminal 106, 108, 110, 112, 114 includes one or more fin structures and one or more gate structures formed across the one or more fin structures. The fin structures may include multiple channel layers. As shown in FIG. 1, the emitter terminal 106 includes fin structures 206, the base terminal 108 includes fin structures 208, the collector terminal 112 includes fin structures 212, the base terminal 110 includes fin structures 210, and the collector terminal 114 includes fin structures 214.

In some embodiments, the number of the fin structures 206 for the emitter terminal 106 may be in a range between 4 and 6. In some embodiments, the number of the fin structures 208, 210 for the base terminal 106, 110 may be in a range between 2 and 4. In some embodiments, the number of the fin structures 212, 214 for the collector terminal 112, 114 may be in a range between 2 and 4.

A plurality of gate structures 250 are formed over the fin structures 206, 208, 210, 212, and 214. In some embodiments, the number of the gate structures 250 may be in a range between 1 and 100, for example between 20 and 80.

In some embodiments, dielectric isolation structures 252 are formed across the gate structures 250 between the fin structures 208 and 212 and between the fin structures 210 and 214. In some embodiments, the semiconductor device 100 may include dielectric isolation structures 254 formed across the gate structures 250 between the fin structures 206 and 208 and between the fin structures 206 and 210. The dielectric isolation structures 252, 254 may be formed using a cut metal gate process. The dielectric isolation structures 252, 254 cut the gate structures 250 into electrically isolated gate sections 310, 320, 330, 340, 350. The gate structure sections 310, 320, 330, 340, and 350 are positioned over the fin structures 212, 208, 206, 210, 214.

Epitaxial emitter regions 256 are formed over the fin structures 206 between the gate structures 250. Epitaxial base regions 258 are formed over the fin structures 208 between the gate structures 250. Epitaxial base regions 260 are formed over the fin structures 210 between the gate structures 250. Epitaxial collector regions 262 are formed over the fin structures 312 between the gate structures 250. Epitaxial collector regions 264 are formed over the fin structures 314 between the gate structures 250. The epitaxial regions 256, 258, 260, 262, and 264 are similar to epitaxial source/drain regions of a GAA transistor or FinFET transistor.

In some embodiments, the epitaxial emitter regions 256 are electrically coupled together forming the emitter terminal 106. In some embodiments, the epitaxial emitter regions 256 may be electrically coupled together by connecting the gate structure sections 330 in a metallization layer. Similarly, the epitaxial base regions 258 are electrically coupled together via the gate structure sections 320 forming the base terminal 108, the epitaxial base regions 260 are electrically coupled together via the gate structure sections 340 forming the base terminal 110, the epitaxial collector regions 262 are electrically coupled together via the gate structure sections 310 forming the collector terminal 112, the epitaxial collector regions 264 are electrically coupled together via the gate structure sections 350 forming the collector terminal 114.

Optionally, the dielectric isolation structures 254 may be omitted allowing the emitter terminal 106 to electrically tied to the base terminals 108, 110 by the gate structures 250.

In some embodiments, the active area, defined by the width W1 and the length L1, may be surrounded by an inactive area. A shallow trench isolation region (STI) 240 may surround the active area. The STI 240 also extends between fin structures 212, 208, 206, 210, and 214. In some embodiments, inactive gates 360 are formed in the inactive area. The inactive gates 360 may be dummy gates, poly gates, or metal gates. Where the gates are metal gates or poly gates, conductive features are not formed to reach the inactive gates 360, thereby, the inactive gates 360 float electrically during operation.

In the example described herein, the BJTs 12, 14 are PNP-type BJTs. The emitter terminal 106 is emitter terminal 106 doped with p-type dopants, the base terminals 108, 110 are n-wells doped with n-type dopants, and the collector terminals 112, 114 are p-wells 112 and 114 doped with p-type dopants. The fin structures 212, 208, 206, 210, and 214 are formed from these doped well regions. Alternatively, the BJTs 12, 14 may be NPN-type BJTs.

FIG. 1 also illustrates that the gate structure sections 320 over the fin structures 208 and the gate structure sections 330 over the fin structures 206 are laterally separated the dielectric isolation structure 254. In some embodiments, the dielectric isolation structure 254 has a width W2, which is an end-to-end distance between the gate structure sections 330 and 320. In some embodiments, the width W2 is in a range between 45 nm and 80 nm. The gate structure sections 320 over the fin structures 208 and the gate structure sections 310 over the fin structures 212 are laterally separated the dielectric isolation structure 252. In some embodiments, the dielectric isolation structure 252 has a width W3, which is an end-to-end distance between the gate structure sections 320 and 310. In some embodiments, the width W3 is in a range between 45 nm and 80 nm. Similarly, an end-to-end distance between the gate structure sections 330 and 340 is the width W2, which is in a range between 45 nm and 80 nm. An end-to-end distance between the gate structure sections 340 and 350 is the width W3, which is in a range between 45 nm and 80 nm.

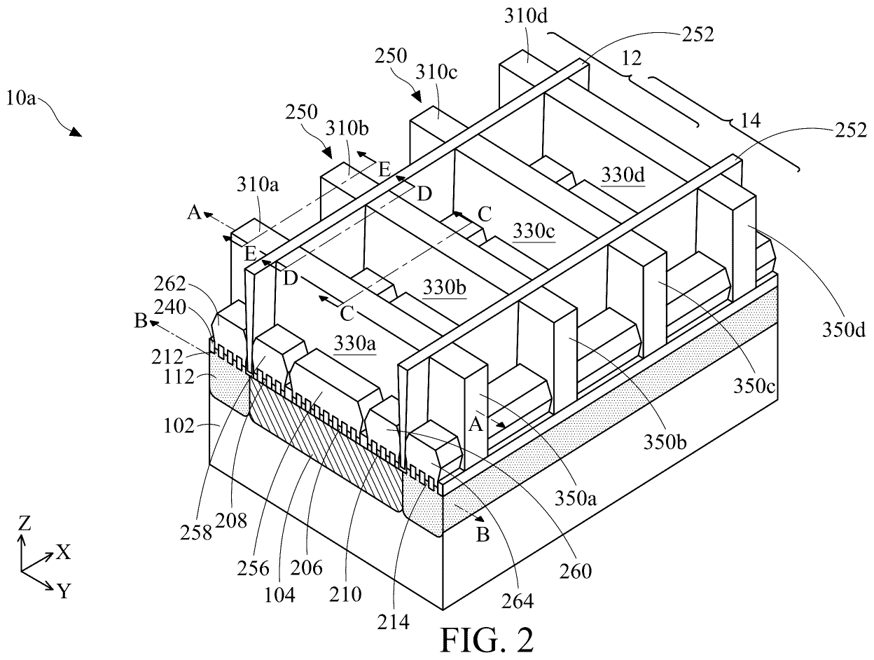

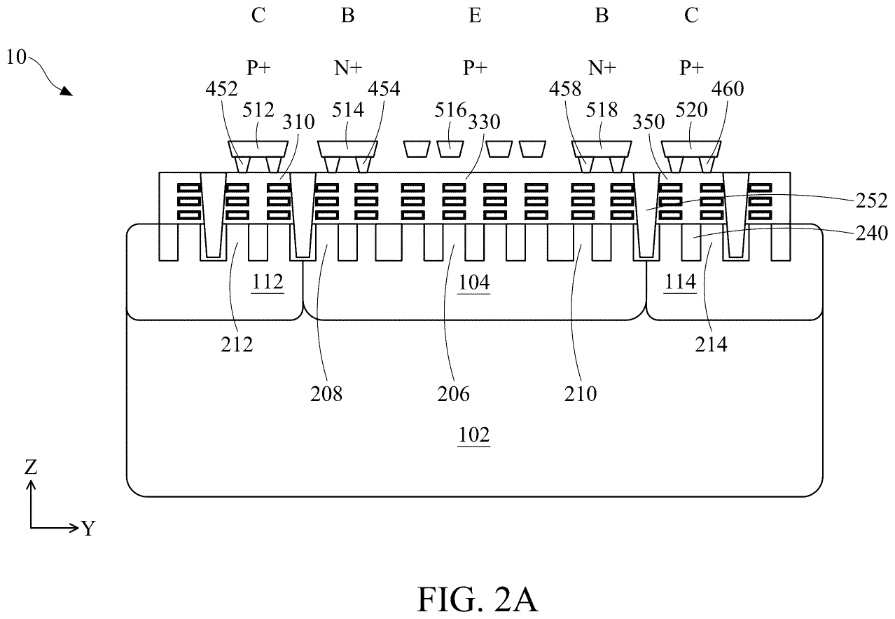

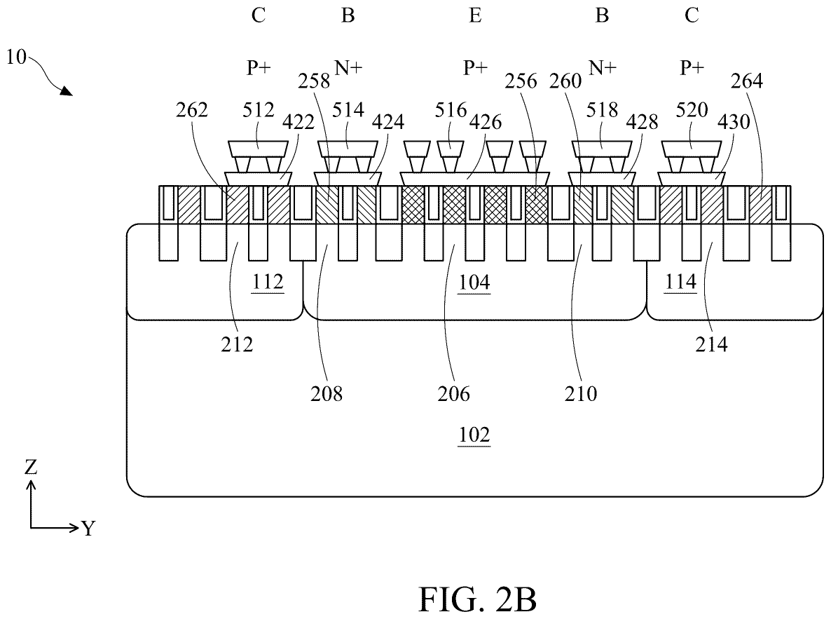

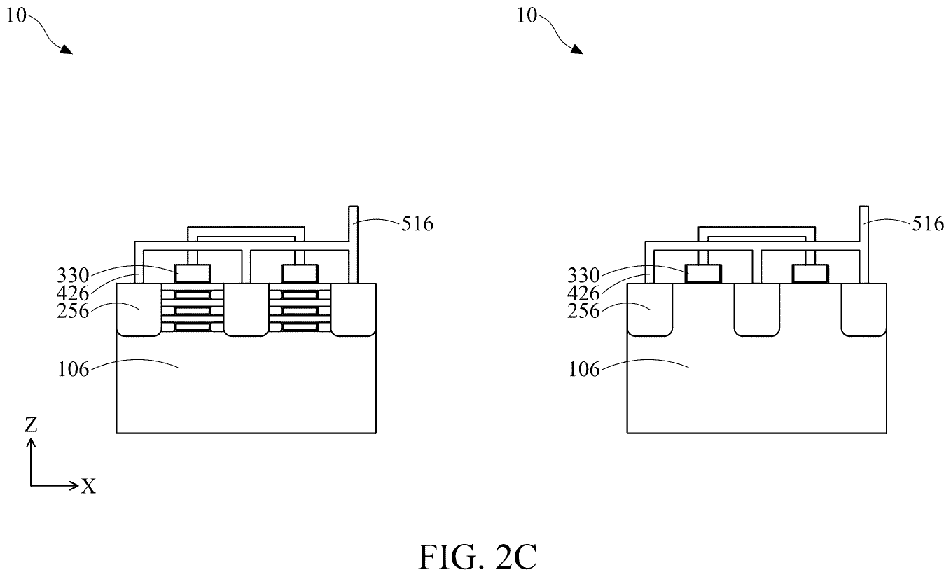

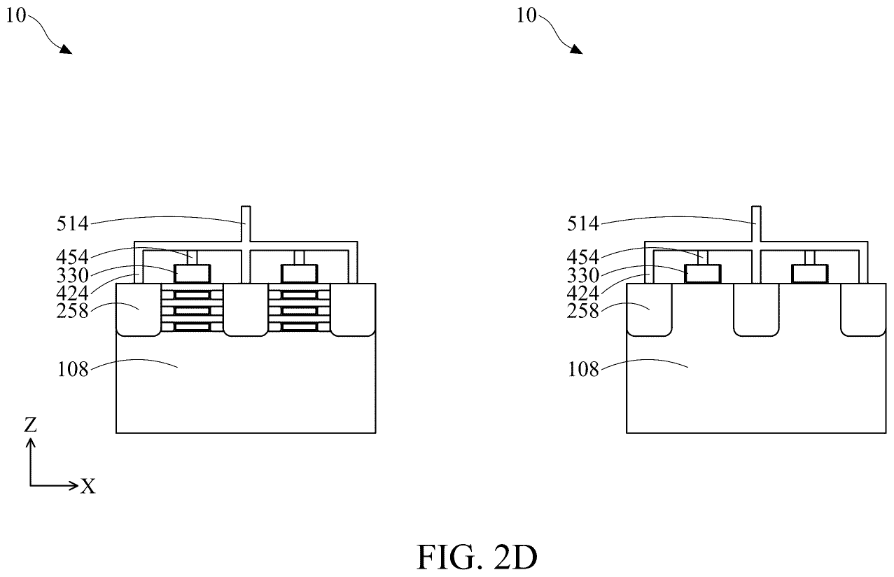

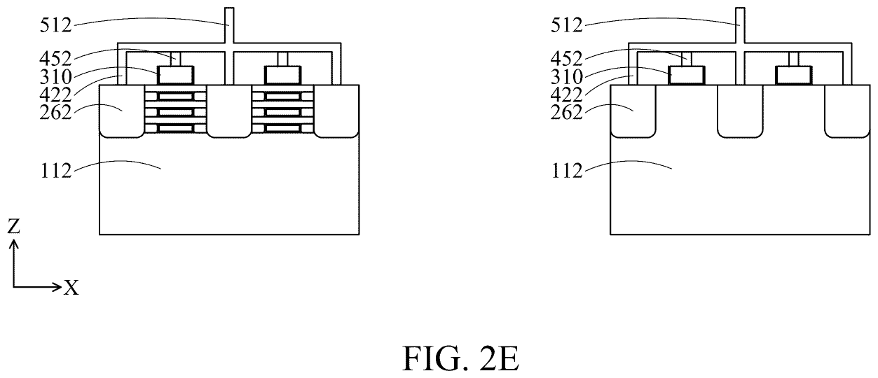

The dashed box 10 in FIG. 1 includes a partial portion of the semiconductor device 100 is defined by the dashed box 10. FIG. 2 schematically illustrates a perspective view of the portion of the semiconductor device 100 marked by the dash box 10 in FIG. 1, which is for simplicity be referred to as the semiconductor device 10 or BJT 10. It should be understood that these views of the semiconductor device 10 may be used to represent any embodiment consistent with those discussed herein. FIG. 2 also provides the cross-sections referred to in the Figures below. Particularly, FIGS. 2A-2E are schematical sectional views of the semiconductor device 10 along the A-A, B-B, C-C, D-D, E-E lines in FIG. 2 respectively.

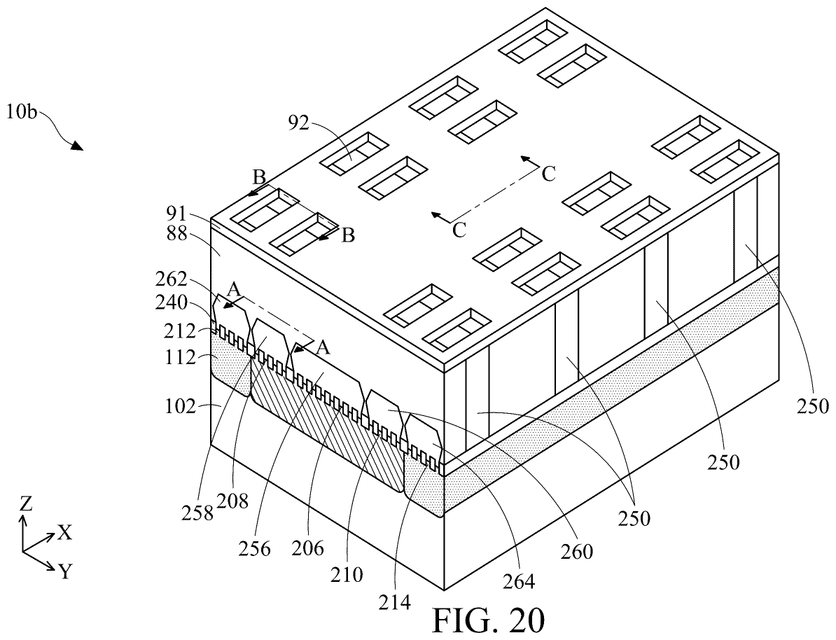

The semiconductor device 10 is similar to the semiconductor device 100 in FIG. 1 except that the semiconductor device 10 does not include the dielectric isolation structures 254, leaving the gate structure of the emitter terminal 106 coupled to the gate structures of the base terminals 108, 110. The semiconductor device 10 may be a BJT with GAA transistors or a BJT with FinFET transistors. FIGS. 20, 2D, 2E schematically illustrate the cross sections for both GAA transistors and FinFET transistors.

As shown in FIGS. 2A-2E, the dielectric isolation structures 252 divide the gate structure 250 between the collector terminals 112/114 and the base terminals 108/110. Gate structures of the emitter terminal 106 and the base terminals 108, 110 are connected. Terminal contacts 422, 424, 426, 428, and 430 and the gate contacts 452, 454, 458, and 460 are disposed above the epitaxial regions and gate structure. Connecting features 512, 514, 516, 518, and 520 are disposed above to provide wiring and connection.

In some embodiments, the connecting features 512, 514, 518, and 520 respectively couple the gate contacts 452, 454, 458, 460 to each other, as shown in FIG. 2A. In some embodiments, the connecting features 512, 514, 516, 518, and 520 respectively couple the terminal contacts 422, 424, 426, 428, and 430 between different epitaxial regions to each other, as shown in FIG. 2B. For the emitter terminal 106, the gate structures of the emitter terminal 106 are electrically coupled to the base terminal 108 and 110.

For the emitter terminal 106, the connecting feature 516 electrically couple to the terminal contacts 426 while the gate structures 330 is tied to the base terminal 108/110, as shown in FIG. 2C. For the base terminal 108, the connecting feature 514 electrically couple the gate contacts 454 electrically with the terminal contacts 424, as shown in FIG. 2D. Similarly, for the base terminal 110, the connecting feature 518 electrically couple the gate contacts 458 electrically with the terminal contacts 428. For the collector terminal 112, the connecting feature 512 may electrically couple the gate contacts 452 with the terminal contacts 422, as shown in FIG. 2E. Similarly, for the collector terminal 114, the connecting feature 520 may electrically couple the gate contacts 460 with the terminal contacts 430.

In other words, for collector terminals and the base terminals, the gate electrodes are coupled to the adjacent epitaxial regions. For example, connecting features 512 may couple the gate contacts 452 together with the terminal contacts 422, thereby coupling together the epitaxial collector regions 262 on the fin structures 212 with the gate structure section 310. Similarly, connecting features 514 may couple together epitaxial base regions 258 on the fin structures 208 with the gate structure section 330, connecting features 518 may couple together epitaxial base regions 260 on the fin structures 210 with the gate structure section 330, and connecting features 520 may couple together epitaxial collector regions 264 on the fin structures 214 with the gate structure section 350.

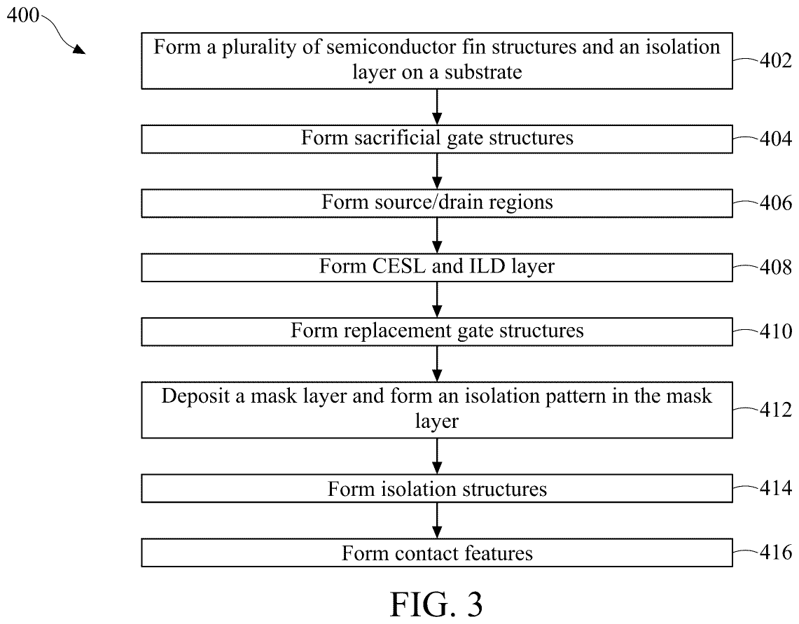

FIG. 3 is a flow chart of a method 400 for forming a bipolar junction transistor device according to embodiments of the present disclosure. FIGS. 4-10, 10A-10C, 11, 11A-11C, 12, 12A-12C, 13, 13A-13C, 14, 14A-14C, 15, 15A-15C, and 16A-16C illustrate various views of intermediate stages in the manufacturing of a semiconductor device 10, in accordance with some embodiments.

In operation 402, a plurality of semiconductor fin structures 205 are formed over a substrate 102 and a shallow trench isolation STI 240 formed around a lower portion of the fin structures 250, as shown in FIGS. 4-9, which are perspective views of the semiconductor device 10.

In FIG. 4, a semiconductor substrate 102 is provided. In some embodiments, the semiconductor substrate 102 includes a crystalline silicon substrate (e.g., wafer). In some embodiments, the semiconductor substrate 102 may be a bulk silicon substrate. In other embodiments, the semiconductor substrate 102 may be a silicon-on-insulator (SOI) substrate or a germanium-on-insulator (GOI) substrate. The semiconductor substrate 102 may be a p-type substrate, that is, semiconductor substrate 102 may be doped with p-type dopants (also referred to as impurities). The semiconductor substrate 102 may also include additional doped wells which are doped with n-type or p-type dopants forming well regions comprising n-type doped wells and p-type doped wells depending on design requirements. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

In some embodiments, the semiconductor substrate 102 include a deep n-well 104. For example, the n-well 104 is doped with n-type dopants and is positioned below other wells formed in the substrate 102. The n-well 104 also spans the underside of the other wells formed in the substrate 102 at the surface of the substrate 102. The n-well 104 may be formed by masking areas of the substrate 102 which are not to be implanted and performing a deep implant of n-type impurities. The n-type impurities may include phosphorus, arsenic, antimony, or the like, or a combination thereof implanted in the n-well 104 to a concentration of equal to or less than 10¹⁹ cm⁻³, such as between about 10¹⁶ cm⁻³ and about 10¹⁹ cm⁻³, though other concentrations may be used and are contemplated.

The emitter terminal 106 is formed to span a width of a center portion of the n-well 104. The base terminal 108 and the base terminal 110 are formed on either side of the emitter terminal 106. The collector terminal 112 and the collector terminal 114 are formed on either side of the base terminal 108 and the base terminal 110, respectively. The emitter terminal 106 will serve as a coupled emitter for a pair of BJTs formed in the device 10, for example the BJT 12 and BJT 14 in FIG. 1. In some embodiments, the collector terminals 112, 114, and base terminals 108, 110 of the pair of BJTs may also be coupled together to form effectively a single BJT. The base terminal 108 and the base terminal 110 will serve as a respective base for each of the pair of BJTs, and the collector terminal 112 and the collector terminal 114 will serve as a respective collector for each of the pair of BJTs.

In some embodiments, epitaxial material, either an epitaxial layer or an epitaxial material stack is formed over the substrate for forming fin structures thereon. In some embodiments, a semiconductor stack 130 are formed over the semiconductor substrate 102 with the GAA process. The semiconductor stack 130 includes alternating semiconductor layers made of different materials to facilitate formation of nanosheet channels in a multi-gate device, such as nanosheet channel FETs. In some embodiments, the semiconductor stack 130 includes first semiconductor layers 132 interposed by second semiconductor layers 134 The first semiconductor layers 132 and second semiconductor layers 134 have different oxidation rates and/or etch selectivity. In later fabrication stages, portions of the semiconductor layers 134 form nanosheet channels in a multi-gate device, including transistors for the BJTs. Three first semiconductor layers 132 and three second semiconductor layers 134 are alternately arranged as illustrated as an example. More or less semiconductor layers 132 and 134 may be included in the semiconductor stack 130 depending on the desired number of channels in the semiconductor device to be formed. In some embodiments, the number of semiconductor layers 132, 134 is between 1 and 10.

The semiconductor layers 132, 134 may be formed by a molecular beam epitaxy (MBE) process, a metalorganic chemical vapor deposition (MOCVD) process, and/or other suitable epitaxial growth processes. In some embodiments, the semiconductor layers 132 and 134 are made of materials having different lattice constants. In some embodiments, the first semiconductor layers 132 include an epitaxially grown silicon germanium (SiGe) layer and the second semiconductor layers 134 include an epitaxially grown silicon (Si) layer. Alternatively, in some embodiments, either of the semiconductor layers 132 and 134 may include other materials such as Ge, a compound semiconductor such as SiC, GeAs, GaP, InP, InAs, and/or InSb, an alloy semiconductor such as SiGe, GaAsP, AlInAs, AlGaAs, InGaAs, GaInP, and/or GaInAsP, or combinations thereof. In some embodiments, the semiconductor stack 130 may have the same type of dopants as the terminals underneath.

In some embodiments, each second semiconductor layer 134 has a thickness in a range between about 5 nm and about 30 nm. In other embodiments, each second semiconductor layer 134 has a thickness in a range between about 10 nm and about 20 nm. In some embodiments, each second semiconductor layer 134 has a thickness in a range between about 6 nm and about 12 nm. In some embodiments, the second semiconductor layers 134 in the semiconductor stack 130 are uniform in thickness. The first semiconductor layers 132 in channel regions may eventually be removed and serve to define a vertical distance between adjacent channel regions for a subsequently formed multi-gate device. In some embodiments, the thickness of the first semiconductor layer 132 is equal to or greater than the thickness of the second semiconductor layer 134. In some embodiments, each semiconductor layer 132 has a thickness in a range between about 5 nm and about 50 nm. In other embodiments, each first semiconductor layer 132 has a thickness in a range between about 10 nm and about 30 nm.

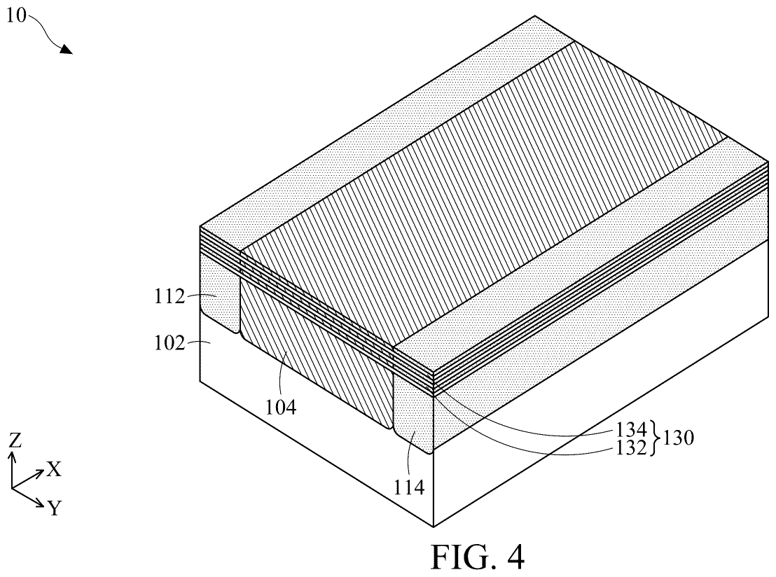

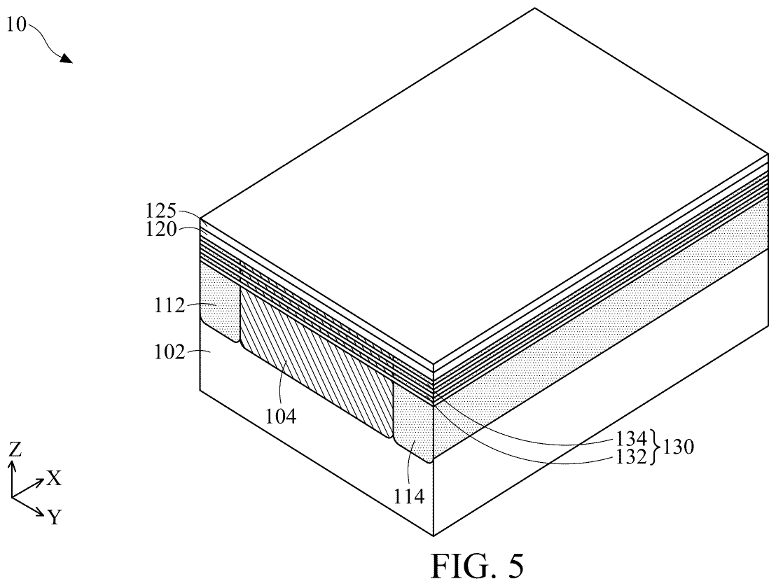

As shown in FIG. 5, a pad layer 120 and a mask layer 125 are sequentially formed the semiconductor stack 130. The pad layer 120 a may be a silicon oxide thin film formed, for example, by thermal oxidation process. The pad layer 120 may act as an adhesion layer between the semiconductor stack 130 and the mask layer 125. The pad layer 120 may also act as an etch stop layer for etching the mask layer 125. For example, the mask layer 125 may be a silicon nitride layer formed by low-pressure chemical vapor deposition (LPCVD) or plasma enhanced chemical vapor deposition (PECVD). The mask layer 125 may be used as a hard mask during subsequent etching processes.

In FIG. 6, a plurality of fin structures 205 are formed. The mask layer 125 may be patterned using a photolithography technique. The pad layer 120 may be etched based on the pattern of the mask layer 125, using the mask layer as an etch mask, thereby exposing upper surfaces of the semiconductor stack 130. The upper surface of the semiconductor stack 130 which is uncovered by the mask layer 125. The semiconductor stack 130 and the terminals 106, 108, 110, 112, and 114 are then etched to form trenches therebetween and the fin structures 205. The fin structures 206 are formed on and in the emitter terminal 106, the fin structures 208 are formed on and in the base terminal 108, the fin structures 210 are formed on and in the base terminal 110, the fin structures 212 are formed on and in the collector terminal 112, and the fin structures 214 are formed on and in the collector terminal 114. The number of fins and trenches can vary depending on design. The etching may be any acceptable etch process, such as a reactive ion etch (RIE), neutral beam etch (NBE), the like, or a combination thereof. The etch may be anisotropic. The active region, such as described above with respect to FIG. 1 may also be defined, etching the substrate to form the ends of the fin structures 206, 208, 210, 212, and 214. In some embodiments, the fin structures 206, 208, 210, 212, and 214 may be formed first and then cut to a desired length (e.g., length L1) in a subsequent process.

The fin structures 206, 208, 210, 212, and 214 may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. In some embodiments, the mask (or other layer) may remain on the fins.

The height of the fin structures 206, 208, 210, 212, and 214 may be between about 100 nm to about 150 nm, though other values may be used and are contemplated. The pitch from fin to fin of the fin structures 206, 208, 210, 212, and 214 may be between about 15 nm and about 80 nm. The spacing between one fin sidewall and the sidewall of an adjacent fin structure may be between 40 nm and 100 nm. Other dimensions are contemplated and may be used for the fin.

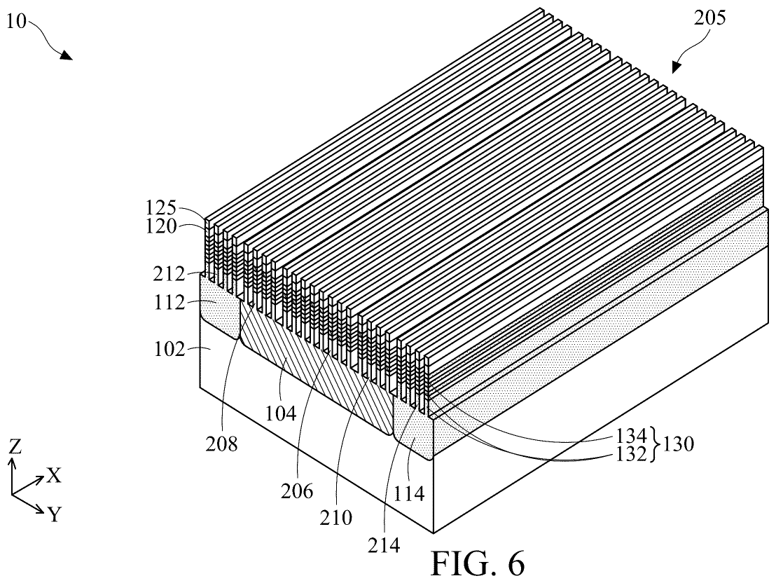

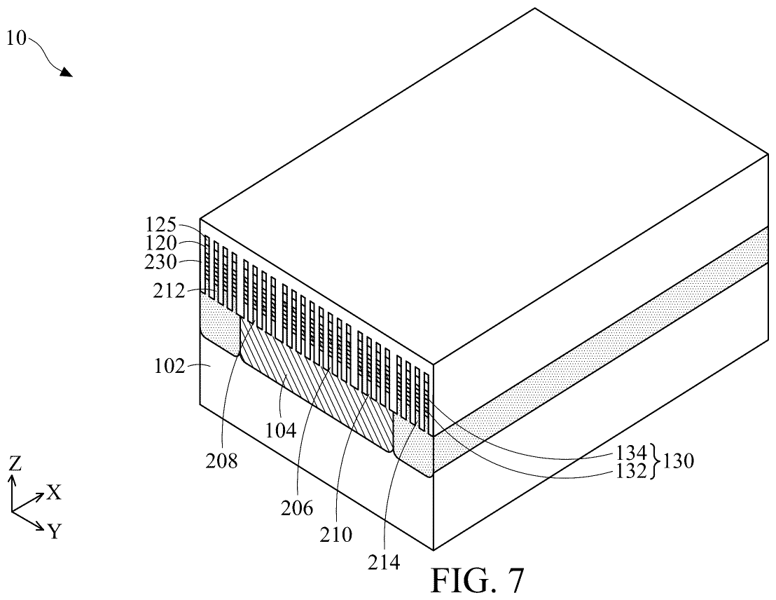

In FIG. 7, an insulating material 230 is formed over the fin structures 206, 208, 210, 212, and 214 and fills the trenches between the fin structures 206, 208, 210, 212, and 214. The insulation material 230 may be an oxide, such as silicon oxide, a nitride, such as silicon nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material 230 is silicon oxide formed by a FCVD process. An anneal process may be performed once the insulation material 230 is formed. In an embodiment, the insulation material 230 is formed such that excess insulation material 230 covers the fin structures 206, 208, 210, 212, and 214. Although the insulation material 230 is illustrated as a single layer, some embodiments may utilize multiple layers. For example, in some embodiments a liner may first be formed along a surface of the substrate 102 and the fin structures 206, 208, 210, 212, and 214. Thereafter, a fill material, such as those discussed above may be formed over the liner.

In FIG. 8, a removal process is applied to the insulation material 230 to remove excess insulation material 230 over the fin structures 206, 208, 210, 212, and 214. In some embodiments, a planarization process such as a chemical mechanical polish (CMP), an etch-back process, combinations thereof, or the like may be utilized. The planarization process exposes the fin structures 206, 208, 210, 212, and 214 such that top surfaces of the fins 206, 208, 210, 212, and 214 and the insulation material 230 are level after the planarization process is complete. In embodiments in which a mask remains on the fin structures 206, 208, 210, 212, and 214, the planarization process may expose the mask or remove the mask such that top surfaces of the mask or the fin structures 206, 208, 210, 212, and 214, respectively, and the insulation material 230 are level after the planarization process is complete.

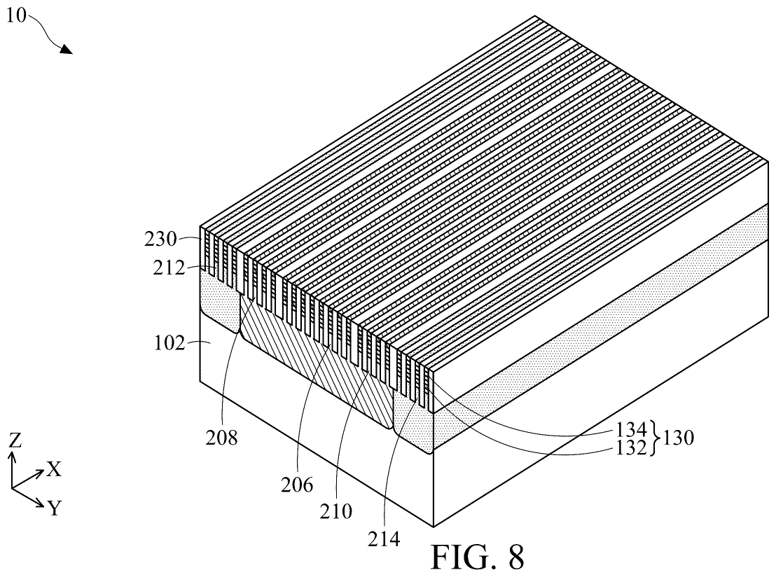

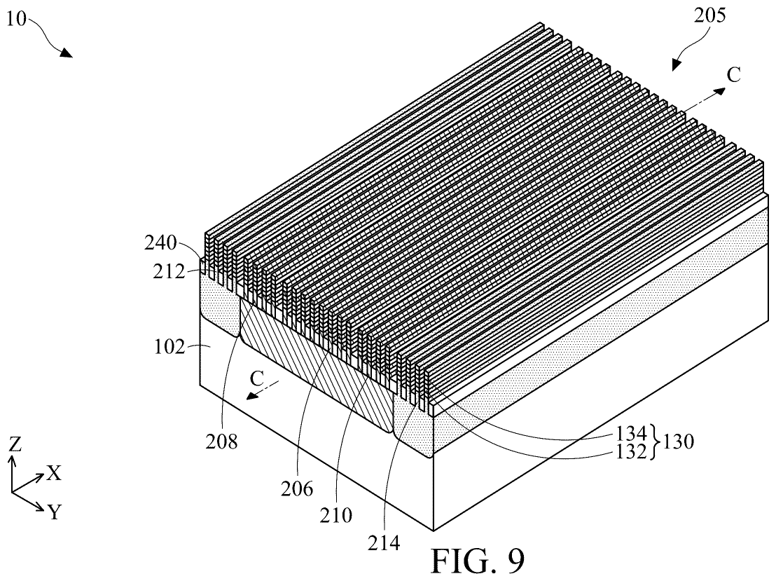

In FIG. 9, the insulation material 230 is recessed to form Shallow Trench Isolation (STI) regions 240. The insulation material 230 is recessed such that upper portions of fin structures 206, 208, 210, 212, and 214 protrude from between neighboring STI regions 240. As shown in FIG. 9, the semiconductor stack 130 portion of the fin structures 206, 208, 210, 212, and 214 are exposed above the STI regions 240. Further, the top surfaces of the STI regions 330 may have a flat surface as illustrated, a convex surface, a concave surface, or a combination thereof. The top surfaces of the STI regions 240 may be formed flat, convex, and/or concave by an appropriate etch. The STI regions 240 may be recessed using an acceptable etching process, such as one that is selective to the material of the insulation material 230 (e.g., etches the material of the insulation material 230 at a faster rate than the material of the fin structures 206, 208, 210, 212, and 214). For example, an oxide removal using, for example, dilute hydrofluoric (dHF) acid may be used.

The process described with respect to FIGS. 4 through 9 is just one example of how the fin structures 206, 208, 210, 212, and 214 may be formed. In some embodiments, the fin structures 206, 208, 210, 212, and 214 may be formed by an epitaxial growth process. For example, a dielectric layer can be formed over a top surface of the substrate 102, and trenches can be etched through the dielectric layer to expose the underlying substrate 102. Homoepitaxial structures can be epitaxially grown in the trenches, and the dielectric layer can be recessed such that the homoepitaxial structures protrude from the dielectric layer to form fins 206, 208, 210, 212, and 214. Additionally, in some embodiments, heteroepitaxial structures can be used for the fins 206, 208, 210, 212, and 214. For example, the fins 206, 208, 210, 212, and 214 in FIG. 6 can be recessed, and a material different from the fins 206, 208, 210, 212, and 214 may be epitaxially grown over the recessed fins 206, 208, 210, 212, and 214. In such embodiments, the fins 206, 208, 210, 212, and 214 comprise the recessed material as well as the epitaxially grown material disposed over the recessed material. In an even further embodiment, a dielectric layer can be formed over a top surface of the substrate 102, and trenches can be etched through the dielectric layer. Heteroepitaxial structures can then be epitaxially grown in the trenches using a material different from the substrate 102, and the dielectric layer can be recessed such that the heteroepitaxial structures protrude from the dielectric layer to form the fins 206, 208, 210, 212, and 214. In some embodiments where homoepitaxial or heteroepitaxial structures are epitaxially grown, the epitaxially grown materials may be in situ doped during growth, which may obviate prior and subsequent implantations although in situ and implantation doping may be used together.

Still further, it may be advantageous to epitaxially grow a material in the base terminal 108 and the base terminal 110 different from the material in the emitter terminal 106, the collector terminal 112, and the collector terminal 114. In various embodiments, upper portions of the fin structures 206, 208, 210, 212, and 214 may be formed from silicon-germanium (SixGe1-x, where x can be in the range of 0 to 1), silicon carbide, pure or substantially pure germanium, a III-V compound semiconductor, a II-VI compound semiconductor, or the like. For example, the available materials for forming III-V compound semiconductor include, but are not limited to, indium arsenide, aluminum arsenide, gallium arsenide, indium phosphide, gallium nitride, indium gallium arsenide, indium aluminum arsenide, gallium antimonide, aluminum antimonide, aluminum phosphide, gallium phosphide, and the like.

In some embodiments, the grown materials of the epitaxial fin structures 206, 208, 210, 212, and 214 may be in situ doped during growth, which may obviate the implantations, although in situ and implantation doping may be used together.

Regardless of the process used to form the fin structures 206, 208, 210, 212, and 214, in some embodiments the fin structures 206, 208, 210, 212, and 214 may be further doped in a separate process to increase the dopant concentration in the fin structures 206, 208, 210, 212, and 214. In some embodiments, the upper portion of the fin structures 206, 208, 210, 212, and 214 may be doped to a concentration between about 10¹⁹ cm⁻³ and about 10²¹ cm⁻³ of additional p-type or n-type impurities as appropriate. Masks may be used to protect parts of the fin structures 206, 208, 210, 212, and 214 while other areas are implanted.

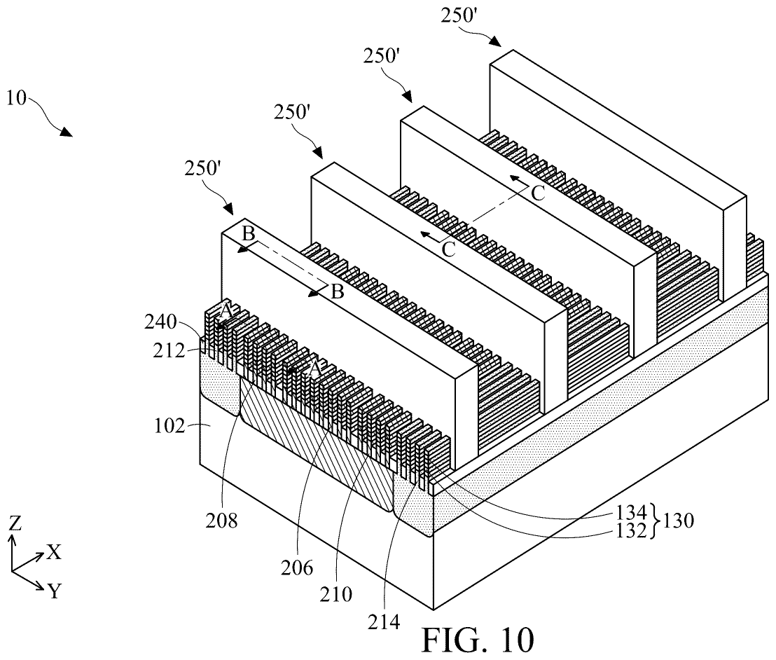

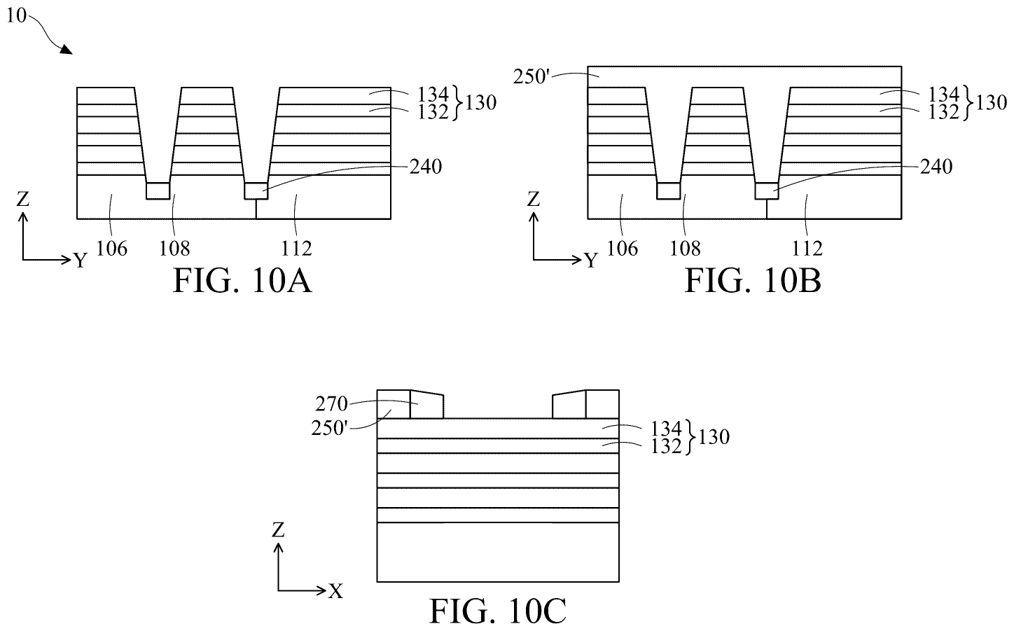

In operation 404, sacrificial gate structures 250′ are formed over the fin structures 205, as shown in FIGS. 10 and 10A-10C. FIG. 10 is a schematic perspective view of the semiconductor device 10. FIGS. 10A-10C are schematic cross-sectional views of the semiconductor device 10 along the lines A-A, B-B, C-C in FIG. 10. The sacrificial gate structures 250′ are formed over the fin structures 205. The sacrificial gate structures 250′ may include a sacrificial gate dielectric layer, a sacrificial gate electrode layer, and sidewall spacers 270. The sacrificial gate structures 250′ are formed over a portion of the fin structures 205 which is to be a channel region.

The sacrificial gate dielectric layer is formed by a blanket deposition over the fin structures 205. A sacrificial gate dielectric layer includes one or more layers of insulating material, such as a silicon oxide-based material. In some embodiments, silicon oxide formed by CVD is used. In some embodiments, the sacrificial gate dielectric layer has a thickness in a range between about 1 nm and about 5 nm. A sacrificial gate electrode layer is then blanket deposited on the sacrificial gate dielectric layer and over the fin structures 205. The sacrificial gate electrode layer includes silicon such as polycrystalline silicon or amorphous silicon. The thickness of the sacrificial gate electrode layer is in a range between about 100 nm and about 200 nm. In some embodiments, the sacrificial gate electrode layer is subjected to a planarization operation. The sacrificial gate electrode layer may be deposited using CVD, including LPCVD and PECVD, PVD, ALD, or other suitable process.

Subsequently, a pad layer and a mask layer are formed over the sacrificial gate electrode layer. The pad layer may include silicon nitride. The mask layer may include silicon oxide. Next, a patterning operation is performed on the mask layer, the pad layer, the sacrificial gate electrode layer, and the sacrificial gate dielectric layer to form the sacrificial gate structure.

After the sacrificial gate structures 250′ are formed, the sidewall spacers 270 are formed by a blanket deposition of an insulating material followed by anisotropic etch to remove insulating material from horizontal surfaces. The sidewall spacers 270 may have a thickness in a range between about 2 nm and about 10 nm. In some embodiments, the insulating material of the sidewall spacers 270 is a silicon nitride-based material, such as SiN, SiON, SiOCN or SiCN and combinations thereof.

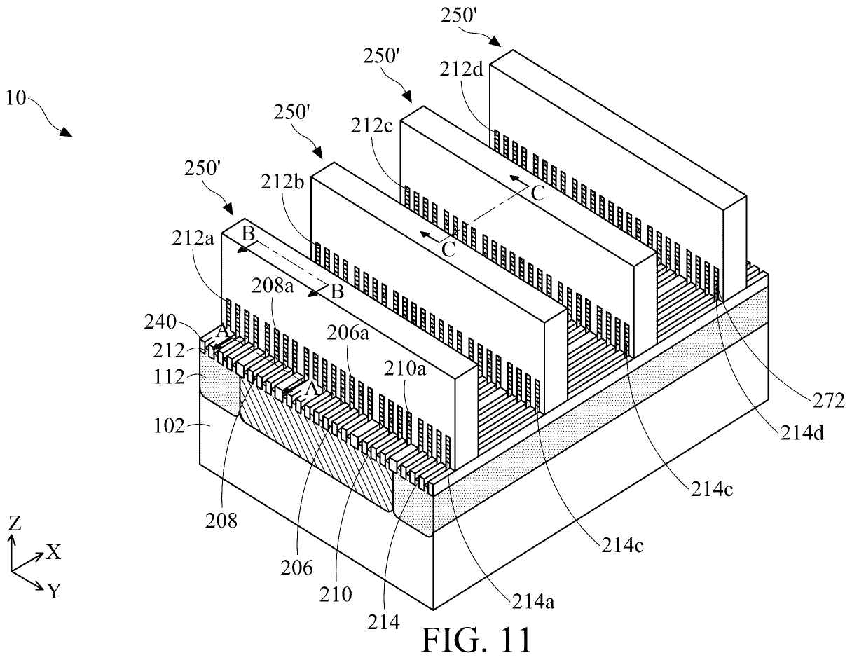

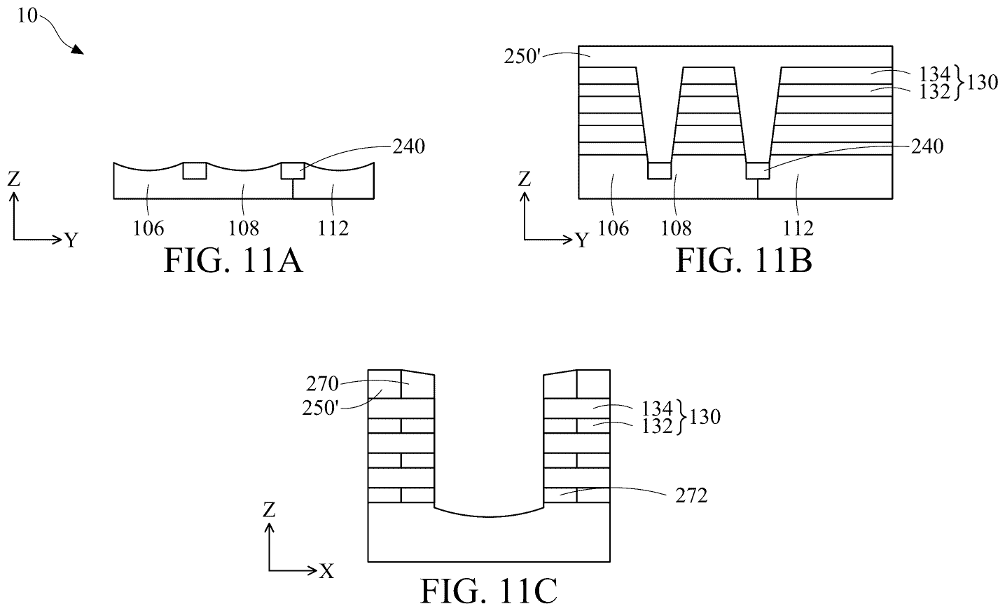

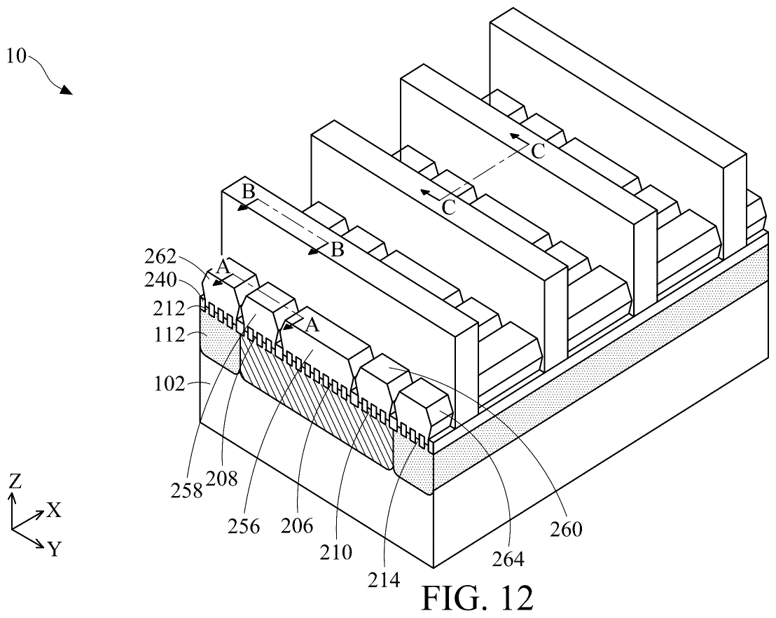

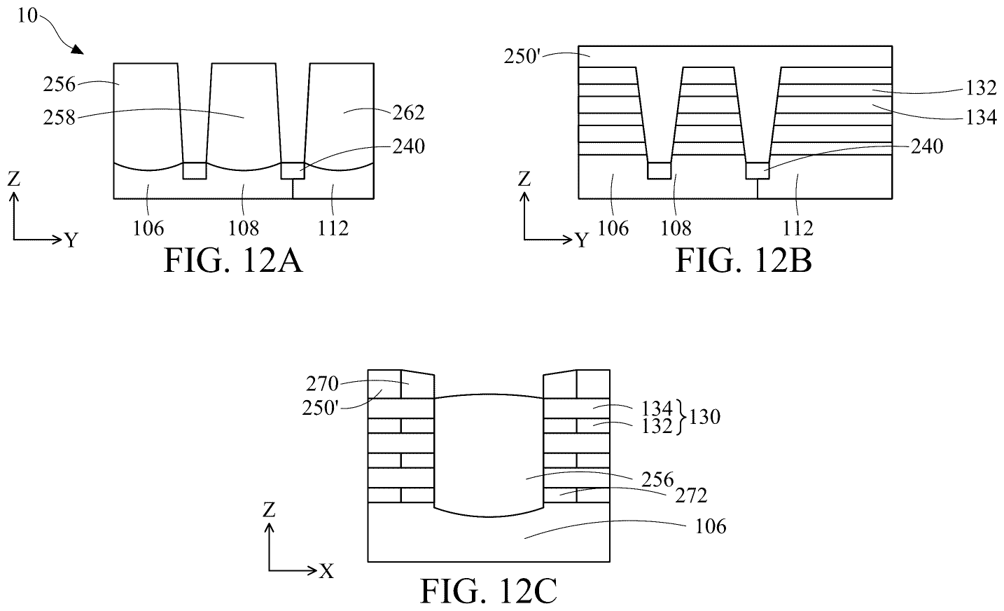

In operation 406, source/drain regions 256, 258, 260, 262, 264 are formed, as shown in FIGS. 11, 11A-11C, and 12, 12A-12C. FIG. 11 is a schematic perspective view of the semiconductor device 10. FIGS. 11A-11C are schematic cross-sectional views of the semiconductor device 10 along the lines A-A, B-B, C-C in FIG. 11. FIG. 12 is a schematic perspective view of the semiconductor device 10. FIGS. 12A-12C are schematic cross-sectional views of the semiconductor device 10 along the lines A-A, B-B, C-C in FIG. 12.

As shown in FIGS. 11, 11A-11C, recesses are formed in the fin structures 206, 208, 210, 212, and 214 between the sacrificial gate structures 250′. The recesses may be formed by etching the fin structures 206, 208, 210, 212, and 214. In some embodiments, the fin structures 206, 208, 210, 212, and 214 may be etched so that the upper surface of the fins 206, 208, 210, 212, and 214 after etching is below an upper surface of the STI 240. In other embodiments, the fin structures 206, 208, 210, 212, and 214 may be etched so that the upper surface of the fin structures 206, 208, 210, 212, and 214 still protrudes from the upper surface of the STI 240 after etching. The semiconductor stack 130 portions are etched away from the fin structures 206, 208, 210, 212, and 214.

Inner spacers 272 are then formed on exposed ends of the first semiconductor layers 132 under the sacrificial gate structure 250′ as shown in FIGS. 11 and 11C. The inner spacers 272 are formed on exposed ends of the first semiconductor layers 132 under the sacrificial gate structure 250. The first semiconductor layers 132 exposed to the recesses are first etched horizontally along the X direction to form cavities. In some embodiments, the first semiconductor layers 132 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. In some embodiments, the amount of etching of the first semiconductor layer 132 is in a range between about 2 nm and about 10 nm along the X direction. After forming cavities in the first semiconductor layers 132, the inner spacers 272 can be formed in the cavities by conformally deposit and then partially remove an insulating layer. The insulating layer can be formed by ALD or any other suitable method. In some embodiments, the insulating layer may include one of silicon nitride (SiN) and silicon oxide (SiO₂) and have a thickness in a range from about 0.5 nm to about 3.0 nm. The subsequent etch process removes most of the insulating layer except inside the cavities, resulting in the inner spacers 272.

As shown in FIGS. 12, 12A-12C, the epitaxial collector regions 262, 264, epitaxial base regions 258, 260, and epitaxial emitter regions 256 are formed in the recesses and over from the fin structures 212, 214, 210, 208, and 206. The epitaxial collector regions 262, 264, the epitaxial base regions 258, 260, and the epitaxial emitter regions 206 are formed from the fin structures 212, 214, 210, 208, and 206 such that the sacrificial gate structures 250′ are disposed between respective neighboring pairs of the epitaxial collector regions 262, 264, the epitaxial base regions 258, 260, and the epitaxial emitter regions 256.

In some embodiments, the epitaxial collector regions 262, 264 and the epitaxial emitter regions 256 are formed in a first epitaxial process because they share the same conductivity and the epitaxial base regions 258, 260 are formed in a second epitaxial process because they share the same opposite conductivity, though either the first or second epitaxial process may be performed first.

In forming the epitaxial collector regions 262, 264 and epitaxial emitter regions 256, a mask may be formed over the structure and patterned to protect the areas where the epitaxial collector regions 262, 264 and epitaxial emitter regions 256 are not to be formed, including the area of the epitaxial base regions 258, 260. The epitaxial collector regions 262, 264 and epitaxial emitter regions 256 may then be selectively grown from the corresponding fin structures. The epitaxial collector regions 262, 264 may be grown from the fins 212 and 214, and the epitaxial emitter regions 256 may be grown from the fins 206. In some embodiments, the epitaxial emitter regions 256 and the epitaxial collector regions 262, 264 are epitaxial-grown silicon germanium (SiGe) by CVD process, and may be in-situ doped during the epitaxial process with a p-type dopant. In some embodiments the epitaxial emitter regions 256 and the epitaxial collector regions 262, 264 may be subsequently or instead doped with an implantation process with a p-type dopant. The p-type dopant for the epitaxial collector regions 262, 264 and epitaxial emitter regions 256 may be any of the p-type impurities (or dopants) previously discussed.

In forming the epitaxial base regions 258, 260, a mask may be formed over the structure and patterned to protect the areas where the epitaxial base regions 258, 260 are not to be formed, including the area of the epitaxial collector regions 262, 264 and the epitaxial emitter regions 256. The epitaxial base regions 258, 260 may then be selectively grown from the fin structures 208 and 210. In some embodiments, the epitaxial base regions 258, 260 are epitaxial-grown silicon (Si), silicon phosphide (SiP), or silicon carbide (SiC) by CVD process, and may be in-situ doped during the epitaxial process with an n-type dopant. In some embodiments the epitaxial base regions 258, 260 may be subsequently or instead doped with an implantation process with an n-type dopant. The n-type dopant for the epitaxial base regions 258, 260 may be any of the n-type impurities (or dopants) previously discussed.

As a result of the epitaxy processes used to form the epitaxial collector region 262, 264, the epitaxial base region 258, 260, and the epitaxial emitter region 256, upper surfaces of these epitaxial regions have facets which expand laterally outward beyond sidewalls of the fin structures 206, 208, 210, 212, and 214. In some embodiments, these facets cause adjacent epitaxial regions from individual fin structures may merge, such as the epitaxial collector region 262, 264, the epitaxial base region 258, 260, and the epitaxial emitter region 256 shown in FIG. 12. In other embodiments, adjacent epitaxial regions from individual fin structures may remain separated after the epitaxy growth process.

Following growing the epitaxial collector regions 262, 264, the epitaxial base regions 258, 260, and the epitaxial emitter regions 256, the dopant concentration for each p-type and n-type dopant in the epitaxial regions may have a concentration between about 10¹⁹ cm⁻³ and about 10²¹ cm⁻³. An anneal may be performed in one or more annealing processes to activate the dopants.

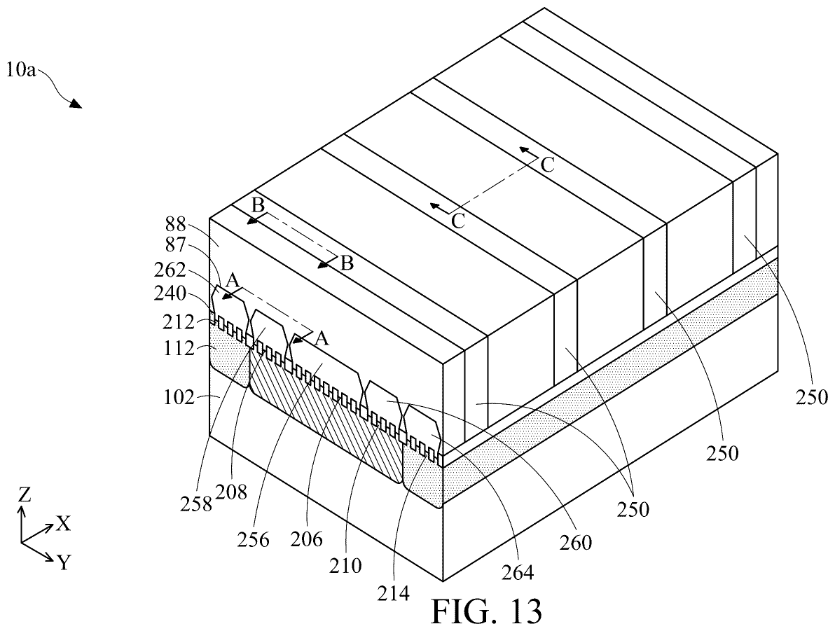

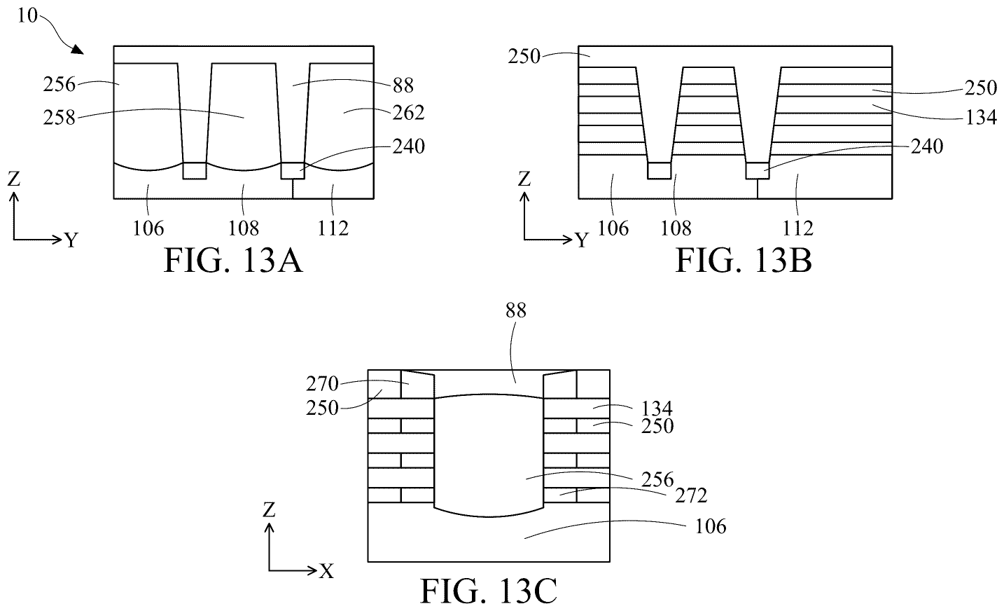

In operation 408, a first interlayer dielectric (ILD) 88 is deposited over the epitaxial regions 256, 258, 260, 262, 264 as shown in FIGS. 13 and 13A-13C. FIG. 13 is a schematic perspective view of the semiconductor device 10. FIGS. 13A-13C are schematic cross-sectional views of the semiconductor device 10 along the lines A-A, B-B, C-C in FIG. 13.

The first ILD 88 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 87 is disposed between the first ILD 88 and the epitaxial collector regions 262, 264, epitaxial base regions 258, 260, the epitaxial emitter regions 256, the STI region 240 and the side wall gate spacers 272. The CESL 87 may comprise a dielectric material, such as, silicon nitride, silicon oxide, silicon oxynitride, or the like, having a different etch rate than the material of the overlying first ILD 88. A planarization process, such as a CMP, may be performed to level the top surface of the first ILD 88 with the top surfaces of the sacrificial gate structures 250′.

In operation 410, the sacrificial gate structures 250′ are removed and the replacement gate structures 250 are formed, as shown in FIGS. 13 and 13A-13C. The replacement gate structure 250 may be formed by removing the sacrificial gate structures 250′, the semiconductor layers 132, and then depositing a gate dielectric layer and a gate electrode layer.

The sacrificial gate structures 250′ are first removed using suitable etching method and the fin structures 205 underneath. The first semiconductor layers 132 are the removed to expose the semiconductor layers 134.

A replacement gate dielectric layer is then deposited conformally in the exposed surfaces, such as the semiconductor layers 134, the emitter terminal 106, the base terminals 108, 110, the collector terminals 112, 114, the sidewall spacers 270, and the inner spacers 272. The replacement gate dielectric layer may be silicon oxide, silicon nitride, or multilayers thereof. In some embodiments, the replacement gate dielectric layer may include a high-k dielectric material, and in these embodiments, the replacement gate dielectric layer may have a k value greater than about 7.0, and may include a metal oxide or a silicate of hafnium, aluminum, zirconium, lanthanum, manganese, barium, titanium, lead, and combinations thereof. The formation methods of the replacement gate dielectric layer may include Molecular-Beam Deposition (MBD), ALD, PECVD, and the like.

A replacement gate electrode layer is deposited over the gate dielectric layer and fill the remaining portions of the recesses. The replacement gate electrode may include a polysilicon or metal-containing material such as titanium nitride, titanium oxide, tantalum nitride, tantalum carbide, cobalt, ruthenium, aluminum, tungsten, combinations thereof, or multi-layers thereof. The replacement gate electrode may comprise any number of liner layers, any number of work function tuning layers, and a fill material. After the filling of the recesses, a planarization process, such as a CMP, may be performed to remove the excess portions of the replacement gate dielectric layer and the material of the replacement gate electrodes, which excess portions are over the top surface of the ILD 88.

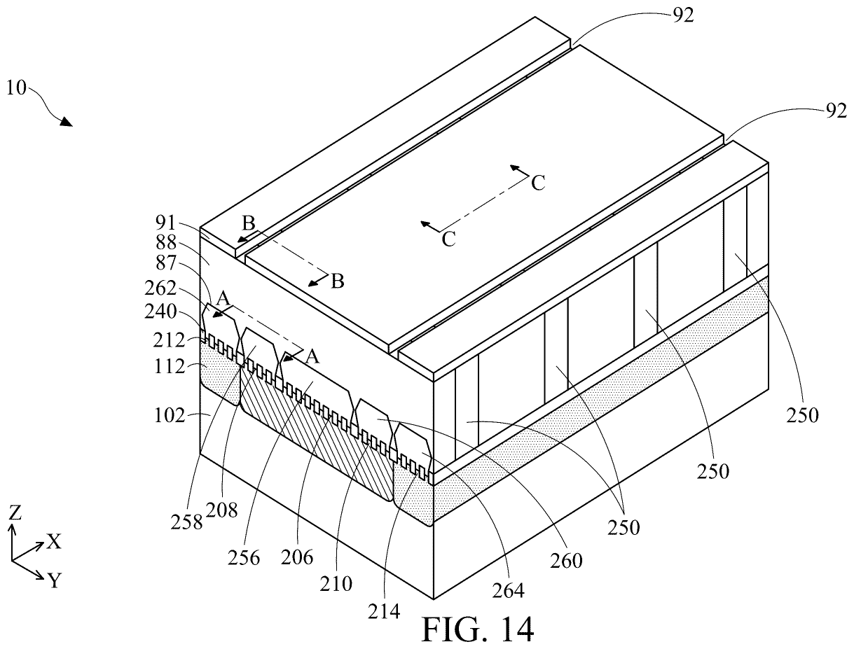

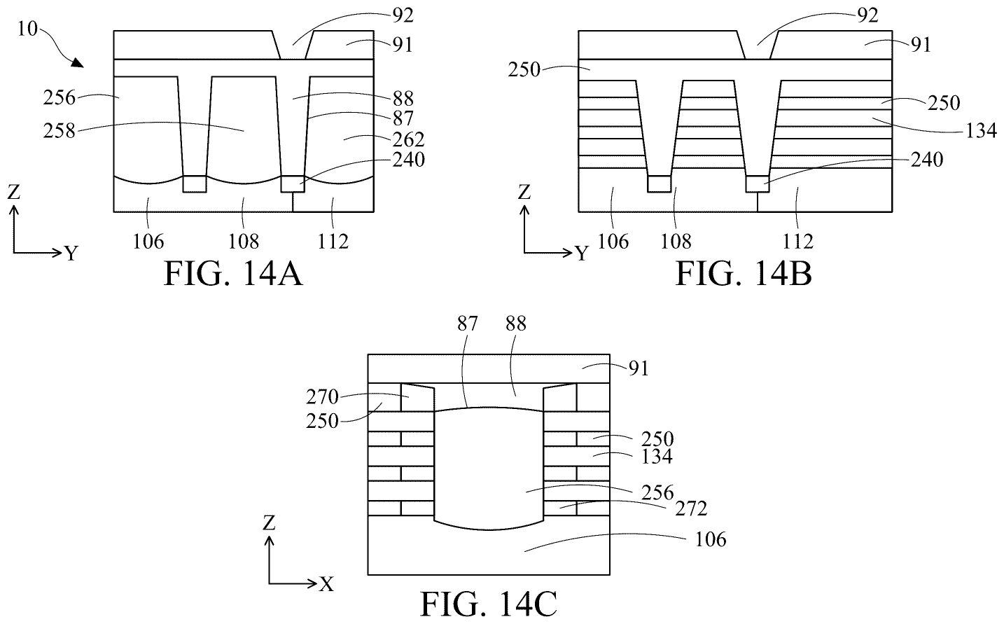

In operation 410, a mask layer 91 is deposited over the replacement gate structures 250 and a dielectric isolation pattern is formed in the mask layer 91, as shown in FIGS. 14 and 14A-14C. FIG. 14 is a schematic perspective view of the semiconductor device 10. FIGS. 14A-14C are schematic cross-sectional views of the semiconductor device 10 along the lines A-A, B-B, C-C in FIG. 14.

After operation 412, the replacement gate structures 250 are continuous structures across the terminals 212, 210, 206, 208, 214. The terminals 212, 210, 206, 208, 214 may be electrically coupled together by the gate electrode layer in the gate structures 250. A cutting process may be performed to cut the continuous gate structures 250 into sections to isolate the terminals 212, 210, 206, 208, 214. In some embodiments, a dielectric isolation process may be performed to cut the replacement gate structures 250 into sections.

In some embodiments, a mask layer 91 may be deposited over the ILD 88 and over top surfaces of the continuous gate structures 250. The mask layer 91 is then patterned using acceptable photolithography techniques to form openings 92 to expose portions of the continuous gate structures 250. In some embodiments, the openings 92 may be a continuous opening along the x-direction or perpendicular to the gate structures 250. The openings 92 may be disposed between the collector terminals 212/214 and the base terminals 208/210. Alternately, additional openings may be formed in operation 412 according to circuit design or to prevent pattern loading during process. For example, additional openings may be formed between the base terminals 208/210 to avoid pattern loading or additional openings may be formed on along boundaries of the active region, for example, outside the collector terminals 212, 214.

In some embodiments, as shown in FIG. 14, the openings 92 extend across the entire length of the BJTs 12, 14. In other embodiments, the openings 92 may be sectioned along the x-direction with each opening 92 extending across a few gate structures 250. For example, each opening may extend across one individual gate structure 250. In some embodiments, the cut pattern in the mask layer 91 may include a combination of openings with various lengths.

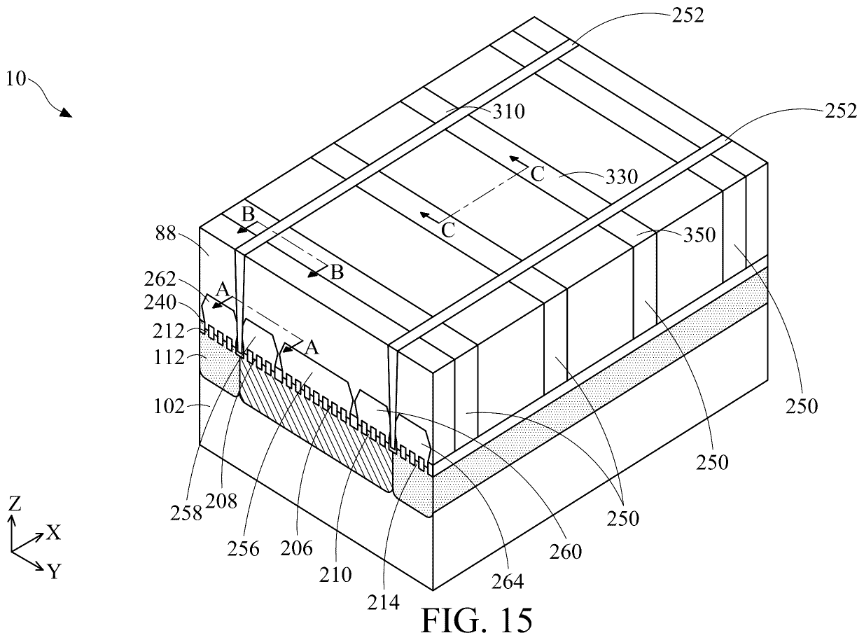

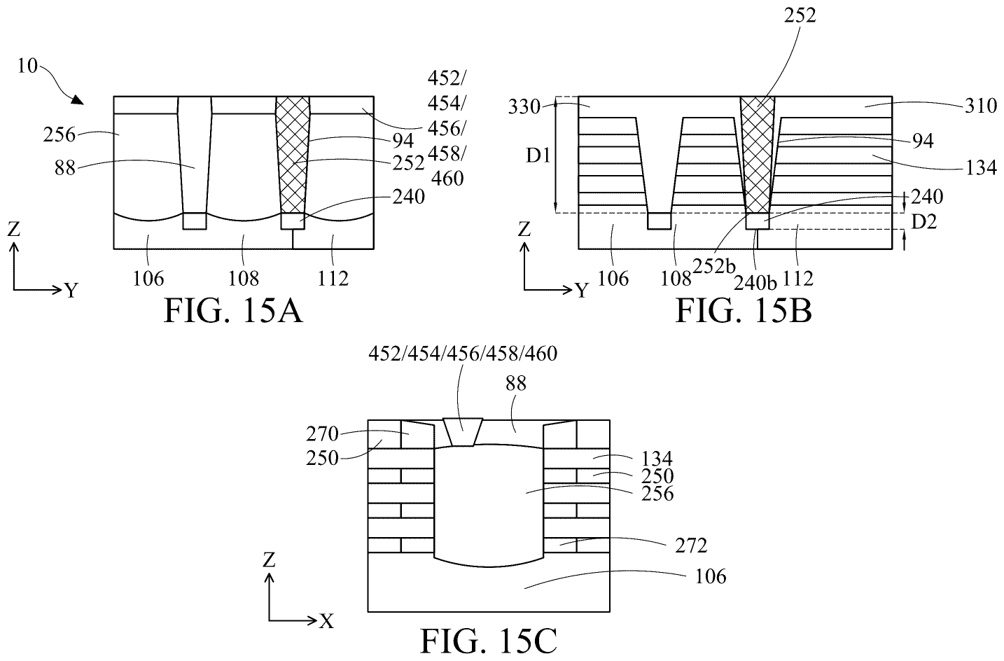

In operation 414, the dielectric isolation structures 252 are formed, as shown in FIGS. 15 and 15A-15C. FIG. 15 is a schematic perspective view of the semiconductor device 10. FIGS. 15A-15C are schematic cross-sectional views of the semiconductor device 10 along the lines A-A, B-B, C-C in FIG. 15.

The dielectric isolation structures 252 are formed using the cutting pattern formed in the mask layer 91. A series of etching processes may be performed to remove materials from exposed portions of the gate structures 250. In some embodiments, other materials exposed to the openings 92, such as the ILD 88, the CESL 87, and any epitaxial base regions 258/260 and epitaxial collector regions 262/264 may also be removed. The etching processes result in trenches 94 across the gate structures 250. In some embodiments, bottoms of the trenches 94 end within the STI 240. That is to say that the trenches 94 do not reach the p-wells or n-wells underneath.

The trenches 94 may be with one or more layers of insulating material using any acceptable techniques. In some embodiments, the insulating material may include a dielectric material such as silicon oxide, silicon nitride, PSG, BSG, BPSG, USG, or the like, and may be deposited by any suitable method, such as CVD and PECVD. A planarization process is followed to expose the remaining gate structures 250.

The dielectric isolation structures 252 divide the continuous gate structures 250 into sections, such as the gate section 330 over the emitter terminal 106 and the base terminals 108, 110, and the gate sections 310, 350 over the collector terminals 112, 114. Insulating material of the dielectric isolation structures 252 is in contact with the gate sections 330, 310, 350. The dielectric isolation structures 252 are also in contact with the first IDL 88, the ECSL 87, and the STI region 240.

As discussed above, the dielectric isolation structures 252 extend into the STI region 240. In some embodiments, a bottom surface 252b of the dielectric isolation structure 252 is disposed in the STI region 240. The dielectric isolation structures 252 do not extend into the well region below the STI region 240. The dielectric isolation structures 252 may have a depth D1 along a z-direction. In some embodiments, the depth D1 is in a range between about 120 nm and 200 nm. The bottom surface 252b and a bottom surface 240b of the STI region 240 is at a distance D2. In some embodiments, the distance D2 is in a range between about 5 nm and about 30 nm. The dielectric isolation structures 252 extend into the STI region 240 to ensure that the dielectric isolation structures 252 disconnect the gate structure sections on opposite sides.

Positioning the dielectric isolation structures 252 above the bottom surface 240b of the STI region 240 prevents degrading of Nf (forward current emission coefficient) of the BJT. It has been observed that Nf_ie trends up with the depth of the dielectric isolation structures 252. The dielectric material, such as SiN, includes in the well portion of the terminals causing the Nf_ie to degrade.

Introducing the dielectric isolation structures reduces current leak Ig from emitter terminal to the base terminal. By using thinner dielectric isolation structures in the gate structures, i.e. positioning the dielectric isolation structure within the STI region, the BJTs according to the present disclosure prevents dielectric isolation induced charge in the terminals.

When forming BJTs using the dielectric isolation process, voltage of the gate structure of the emitter terminal shows strong effects on the BJT performance. When the gate structure of the emitter terminal is tied to the epitaxial regions, the gate structure accumulates lots of charges with leads to l_{b} (base current) recombination. To minimize the gate charge effect, the gate electrode of the emitter terminal may be connected to the base terminal, which may be achieved by leaving the gate structure 250 connected between the emitter terminal 106 and the base terminals 110, 108, as shown in FIGS. 2 and 15.

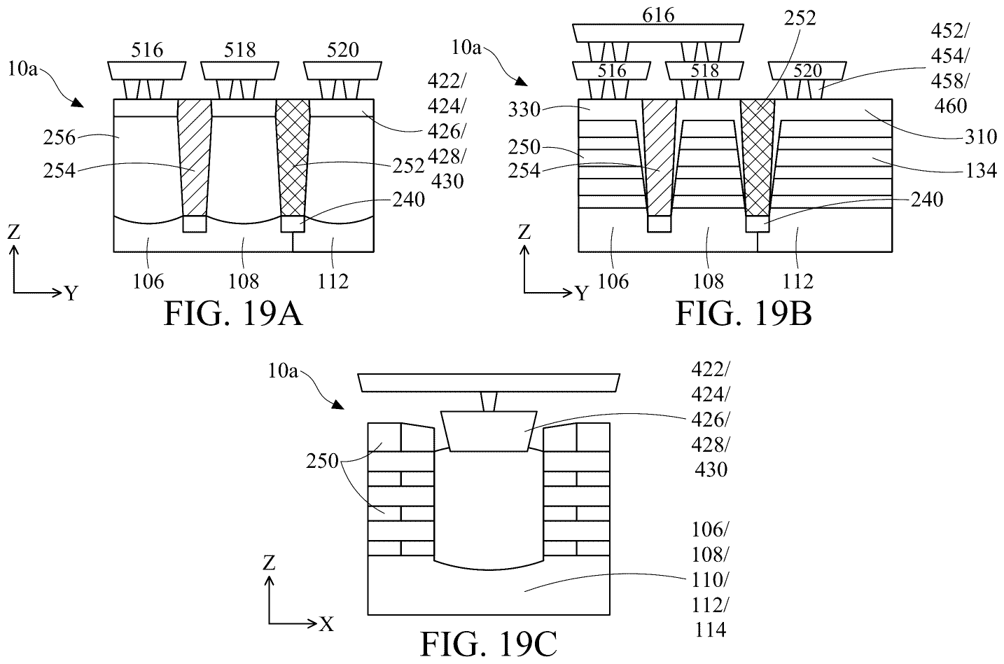

Alternatively, as discussed with FIGS. 17 and 19A-19C, when a dielectric isolation structure is disposed between the emitter terminal 106 and the base terminals 108/110, the gate electrode over the emitter terminal 106 may be connected to the base terminal 108/110 via connectors at an interconnect layer, such as M1 layer.

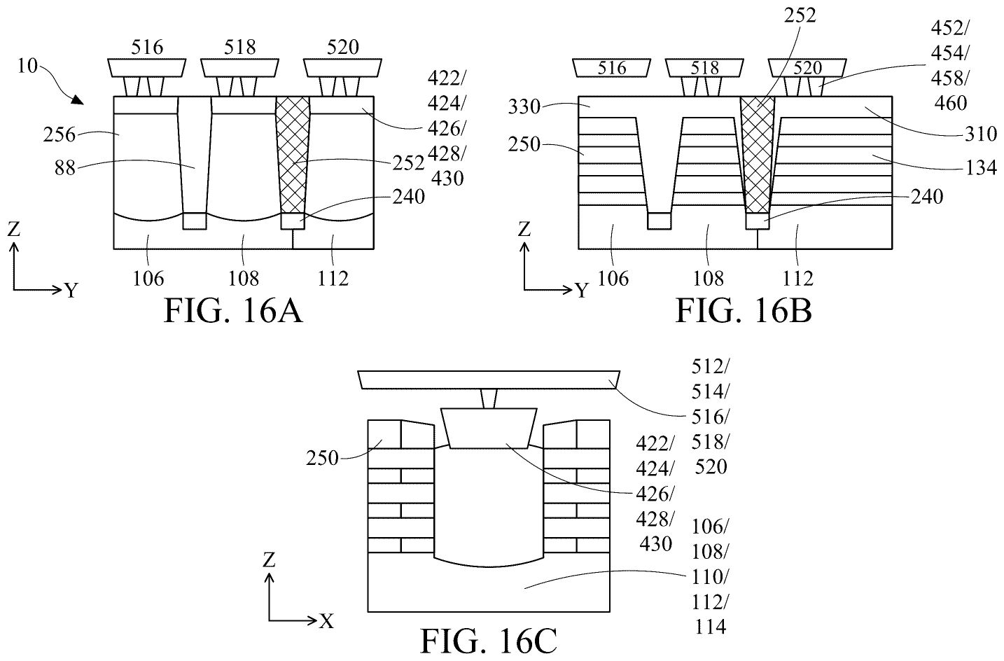

In operation 416, contact features are formed to provide electrical connections to the gate structures and the epitaxial regions, as shown in FIGS. 16A-16C. Conductive features are formed to connect the epitaxial regions and gate structure sections and wire the BJT 10. In some embodiments, gate contacts 452, 454, 458, and 460 and terminal contacts 422, 424, 426, 428, and 430 are formed through one or more ILD layers.

For example, a second ILD layer may be deposited over the first ILD layer 88. Openings for the terminal contacts may be formed through the first and second ILDs, and openings for the gate contacts may be formed through the second ILD. The openings may be formed using acceptable photolithography and etching techniques. A liner, such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the ILD layer. The remaining liner and conductive material form the terminal contacts 422, 424, 426, 428, and 430 and gate contacts 452, 454, 458, and 460. An anneal process may be performed to form a silicide at the interface between the epitaxial collector regions 262, 264, the epitaxial base regions 258, 260, and the epitaxial emitter regions 256 and the corresponding terminal contacts.

The terminal contacts 422 and 430 are physically and electrically coupled to the respective epitaxial collector regions 262, 264, the terminal contacts 424 and 428 are physically and electrically coupled to respective epitaxial base regions 258, 260, and the terminal contacts 426 are physically and electrically coupled to the epitaxial emitter regions 256. The gate contacts 452, 454, 458, and 460 are physically and electrically coupled to the gate structure sections 310, 330, and 350. The terminal contacts 422, 424, 426, 428, and 430 and the gate contacts 452, 454, 458, and 460 may be formed in different processes, or may be formed in the same process.

A metallization layer including a third ILD and connecting features 512, 514, 516, 518, and 520. In some embodiments, the third ILD is a flowable film formed by a flowable CVD method. In some embodiments, the third ILD is formed of a dielectric material such as PSG, BSG, BPSG, USG, or the like, and may be deposited by any suitable method, such as CVD and PECVD. In some embodiments, connecting features 512, 514, 516, 518, and 520 respectively couple the gate contacts 452, 454, 458, and 460 to each other.

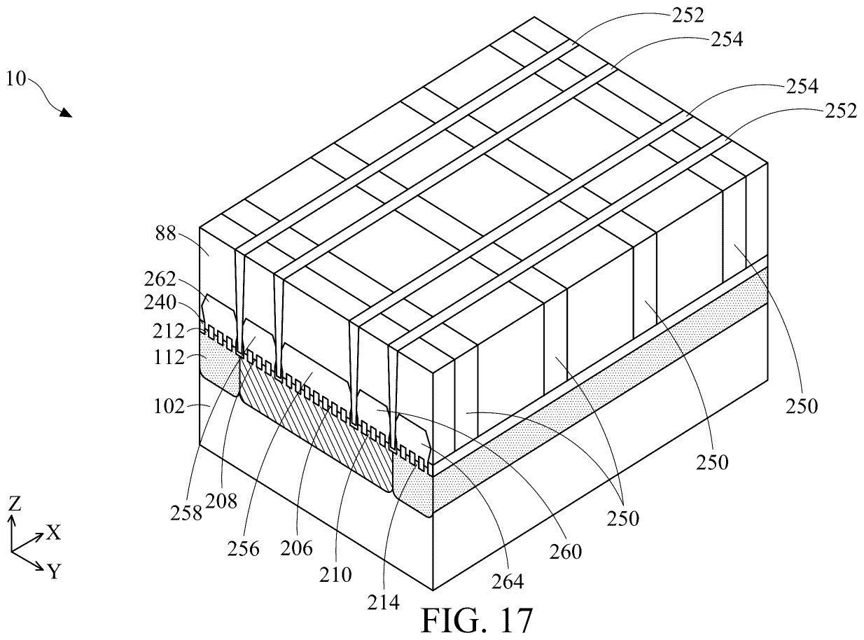

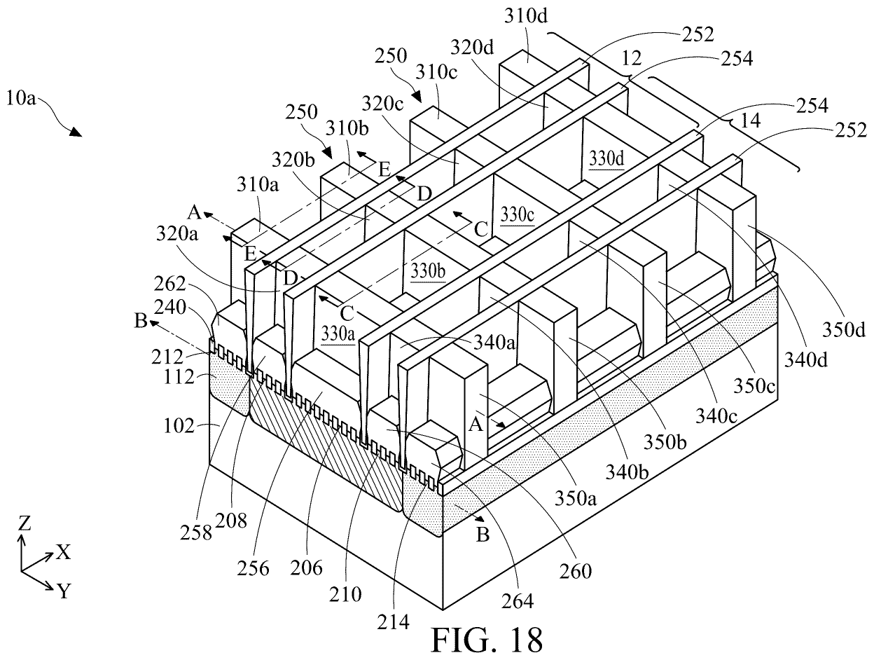

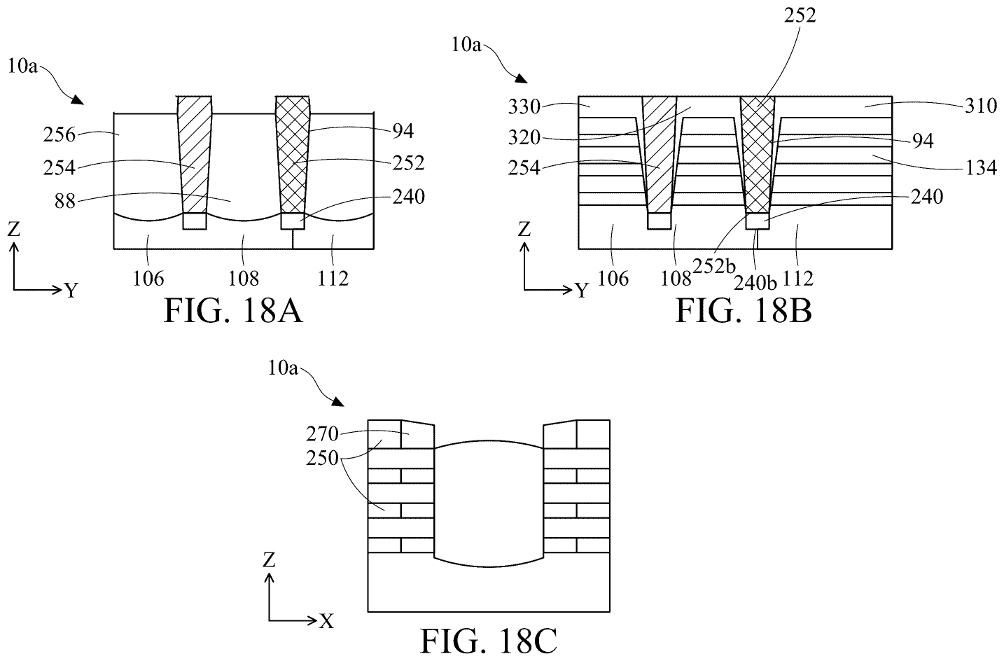

FIGS. 17, 18, 18A-18C, and 19A-19C illustrate a BJT device 10a in accordance with some embodiments. FIG. 17 is a schematic perspective view of the BJT device 10a after operation 414, when the dielectric isolation structures 252, 254 are formed. FIG. 18 is a schematic view of the BTJ device 10a with dielectric material removed to show the gate structures 250 and the dielectric isolation structures 252, 254. FIGS. 18A-18C schematic demonstrate details of the dielectric isolation structures 252, 254 in the BJT device 10a. The BJT device 10a is similar to the BJT device 10 described above except that the BJT device 10a includes additional dielectric isolation structures 254 disposed between the emitter terminal 106 and the base terminals 110, 112. The additional dielectric isolation structures 254 in the BJT device 10a reduce pattern loading during processing. The dielectric isolation structures 254 and 252 divide the continuous gate structures 250 into gate structure sections 310, 320, 330, 340, 350 corresponding to the terminal 112, 108, 106, 110, 114.

FIGS. 19A-19C schematically illustrates the connecting features of the BTJ device 10a. The gate contacts 452, 454, 456, 458, and 460 and terminal contacts 422, 424, 426, 428, and 430 are formed through one or more ILD layers.

The terminal contacts 422 and 430 are physically and electrically coupled to the respective epitaxial collector regions 262, 264, the terminal contacts 424 and 428 are physically and electrically coupled to respective epitaxial base regions 258, 260, and the terminal contacts 426 are physically and electrically coupled to the epitaxial emitter regions 256. The gate contacts 452, 454, 456, 458, and 460 are physically and electrically coupled to the gate structure sections 310, 320, 330, 340, and 350. The terminal contacts 422, 424, 426, 428, and 430 and the gate contacts 452, 454, 456, 458, and 460 may be formed in different processes, or may be formed in the same process.

In some embodiments, the connecting features 512, 514, 516, 518, and 520 respectively couple the terminal contacts 422, 424, 426, 428, and 430 to each other. As such, in some embodiments, the connecting features 512, 514, 516, 518, and 520 may respectively electrically couple the gate contacts 452 with the terminal contacts 422, the gate contacts 454 with the terminal contacts 424, the gate contacts 456 with the terminal contacts 426, the gate contacts 458 with the terminal contacts 428, and the gate contacts 460 with the terminal contacts 430. In other words, the gate electrode for each gate structure sections 310-350 may be coupled to their adjacent epitaxial region. For example, connecting features 512 may couple the gate contacts 452 together with the terminal contacts 422, thereby coupling together the epitaxial collector regions 262 on the fin structures 212 with the gate structure section 310. Similarly, connecting features 514 may couple together epitaxial base regions 258 on the fin structures 208 with the gate structure section 320, connecting features 516 may couple together epitaxial emitter regions 256 on the fin structures 206 with the gate structure section 330, connecting features 518 may couple together epitaxial base regions 260 on the fin structures 210 with the gate structure section 340, and connecting features 520 may couple together epitaxial collector regions 264 on the fin structures 214 with the gate structure section 350.

The BJT device 10a further includes a connecting feature 616 formed in a metallization layer above the connecting features 512, 514, 516, 518, and 520. The connecting feature 616 couples the connecting features 516 and 518, thereby, connecting the gate sections 330 and gate sections 320. The connecting feature 616 connects the gate structures 330 of the emitter terminal 108 with the base terminals 108.

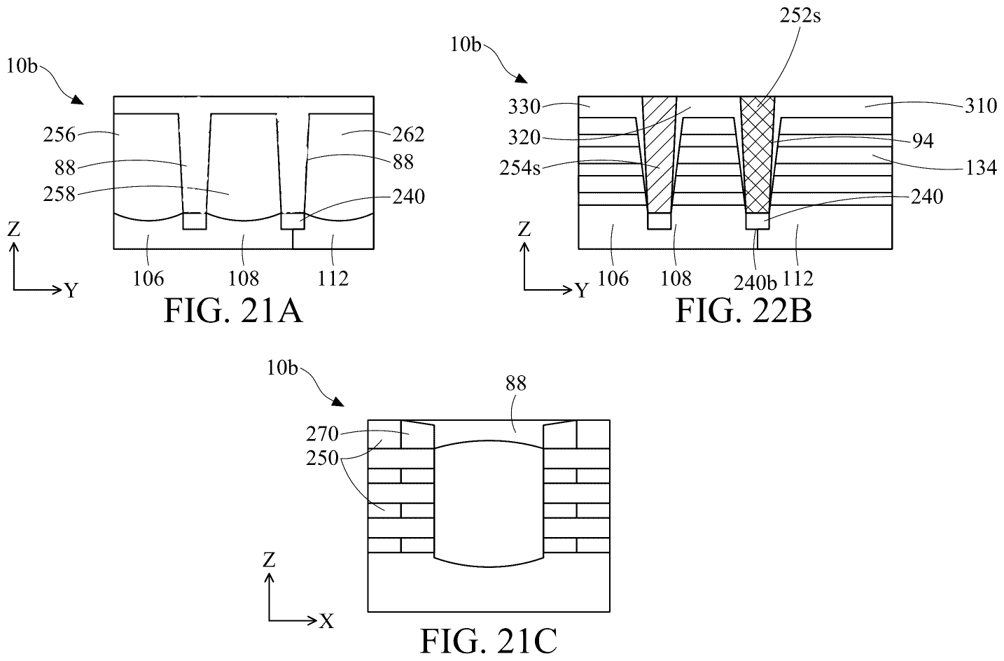

FIGS. 20 and 21A-21C schematically illustrate a BTJ device 10b in accordance with some embodiments. The BTJ device 10b is similar to the BTJ device 10a except that the BTJ device 10b includes a segmented dielectric isolation structures 252s and 254s. The dielectric isolation structures 252s and 254s may be formed using a pattern with openings 93 aligned with the gate structures 250. Each opening 93 may extend across a single gate structure 250, as a result, the dielectric isolation structures 252s, 254s do not extend into the epitaxial regions.

Although the description below corresponds to the formation of a particular arrangement for a p-type BJT (PNP BJT or pBJT), one should understand that the process below may be used for forming variations of the arrangements described above while remaining within the scope of the embodiments. For example, more or fewer gate structures, more or fewer fins, lengths or widths, spacing, polarity (type) and concentration of dopants, and so forth may be adjusted as desired.

Embodiments advantageously use GAA or FinFET processes to form a BJT device. The BJTs according to the present disclosure include dielectric isolation structures to isolate gate structures of the terminals. Using the dielectric isolation structure allows the BJTs to be fabricated with logic devices, such as GAA logic devices. Using dielectric isolation structures reduces emitter to base current leak. The BJTs according to the present disclosure connects gate electrode of the emitter terminal to the base terminal, thereby, minimizing metal gate charging effect. The dielectric isolation structures according to the present disclosure ends within the STI region preventing deep dielectric isolation structures induced substrate fixed charge.

It will be understood that not all advantages have been necessarily discussed herein, no particular advantage is required for all embodiments or examples, and other embodiments or examples may offer different advantages.

Some embodiments of the present disclosure relate to a device comprising a first well in a semiconductor substrate having a first type of dopants; a second well in the semiconductor substrate having a second type of dopants different from the first type, wherein the first well interface with the second well; a first transistor having a first epitaxial region over the first well, wherein the first epitaxial region has the second type of dopants; a second transistor having a second epitaxial region over the first well, wherein the second region has the first type of dopants; a third transistor having a third epitaxial region over the second semiconductor well, wherein the third epitaxial region has the second type of dopants, wherein the second epitaxial region is disposed between the first epitaxial region and the third epitaxial region; and a first dielectric isolation structure disposed between the second transistor and the third transistor

Some embodiments of the present disclosure relate to a device, comprising: a plurality of fin structures extending along a first direction on a substrate, wherein the plurality of fin structures comprising first fin structures, second fin structures, and third fin structures; first epitaxy regions over the first fin structures, the first epitaxy regions providing an emitter terminal for a first bipolar junction transistor (BJT) and a second BJT; second epitaxy regions over the second fins and providing a base terminal for the first BJT; third epitaxy regions over the third fins and providing a collector terminal for the first BJT; a gate structure disposed along a second direction across the plurality of fin structures; and a first dielectric isolation structure disposed between the second fin structures and the third fin structures and across the gate structure.

Some embodiments of the present disclosure relate to a method comprising forming a first well, a second well, and a third well in a substrate, wherein the first well and the third well are doped with a first type of dopants, a second well is doped with a second type of dopants, the second well is disposed between and interface with the first well and the third well along a first direction; forming a plurality of fin structures over the first, second and third well, wherein the plurality of fin structures extends along the first direction; forming a dielectric material around lower portions of the plurality of fin structures; forming a plurality of sacrificial gate structures along a second direction and across the plurality of fin structures; recessing the plurality of fin structures exposed by the plurality of sacrificial gate structures; forming epitaxial regions from the plurality of fin structures; forming replacement gate structures; and forming dielectric isolation structures between the epitaxial regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device, comprising:
a first well in a semiconductor substrate having a first type of dopants;
a second well in the semiconductor substrate having a second type of dopants different from the first type, wherein the first well interfaces with the second well;
a first transistor having a first epitaxial region over the first well, wherein the first epitaxial region has the second type of dopants;
a second transistor having a second epitaxial region over the first well, wherein the second region has the first type of dopants;
a third transistor having a third epitaxial region over the second semiconductor well, wherein the third epitaxial region has the second type of dopants, wherein the second epitaxial region is disposed between the first epitaxial region and the third epitaxial region; and
a first dielectric isolation structure disposed between the second transistor and the third transistor.

2. The device of claim 1, wherein the first transistor comprises a first gate structure disposed adjacent the first epitaxial region, the second transistor comprises a second gate structure disposed adjacent the second epitaxial region, and the third gate structure comprises a third gate structure disposed adjacent the third epitaxial region, and the dielectric isolation structure is disposed between the second gate structure and the third gate structure.

3. The device of claim 2, wherein the dielectric isolation structure extends across the second transistor and the third transistor.

4. The device of claim 2, further comprising:
a first fin structure disposed over the first well, wherein the first gate structure is formed over the first fin structure;
a second fin structure disposed over the first well, wherein the second gate structure is formed over the second fin structure;
a third fin structure disposed over the second well, wherein the third gate structure is formed over the third fin structure; and
an isolation region disposed over the first well and second well and around the first, second and third fins, wherein a bottom surface of the dielectric isolation structure is positioned within the isolation region.

5. The device of claim 2, wherein the first, second, and third gate structures comprise multiple channel layers.

6. The device of claim 2, wherein the first, second, and third gate structures comprises a FinFET channel.

7. The device of claim 2, wherein the first gate structure and the second gate structure are connected.

8. The device of claim 1, further comprising a second dielectric isolation structure disposed between the first transistor and the second transistor.

9. A device, comprising:
a plurality of fin structures extending along a first direction on a substrate, wherein the plurality of fin structures comprising first fin structures, second fin structures, and third fin structures;
first epitaxy regions over the first fin structures, the first epitaxy regions providing an emitter terminal for a first bipolar junction transistor (BJT) and a second BJT;
second epitaxy regions over the second fins and providing a base terminal for the first BJT;
third epitaxy regions over the third fins and providing a collector terminal for the first BJT;
a first gate structure disposed along a second direction across the plurality of fin structures; and
a first dielectric isolation structure disposed between the second fin structures and the third fin structures and across the first gate structure, wherein the first dielectric isolation structure divides the first gate structure to a first gate section disposed over the first and second fin structures, and a second gate section disposed over the third fin structures.

10. The device of claim 9, further comprising:
first terminal contacts in contact with the first epitaxy regions, wherein the first terminal contacts are electrically connected to one another.

11. The device of claim 10, further comprising:
second terminal contacts in contact with the second epitaxy regions, wherein the second terminal contacts are electrically connected to one another and are electrically connected to the first gate section.

12. The device of claim 11, further comprising:
third terminal contacts in contact with the third epitaxy regions, wherein the third terminal contacts are electrically connected to one another and are electrically connected to the second gate section.

13. The device of claim 12, further comprising
a second gate structure disposed along the second direction across the plurality of fin structures, wherein the first dielectric isolation structure divides the second gate structure to a third gate section disposed over the first and second fin structures, and a fourth gate section disposed over the third fin structures.

14. The device of claim 13, further comprising:
a first gate contact feature electrically connecting the first gate section and the third gate section.

15. The device of claim 14, wherein the fourth gate section is electrically connected to the second gate section.

16. A method, comprising:
forming a first well, a second well, and a third well in a substrate, wherein the first well and the third well are doped with a first type of dopants, a second well is doped with a second type of dopants, the second well is disposed between and interface with the first well and the third well along a first direction;
forming a plurality of fin structures over the first, second and third well, wherein the plurality of fin structures extends along the first direction;
forming a dielectric material around lower portions of the plurality of fin structures;
forming a plurality of sacrificial gate structures along a second direction and across the plurality of fin structures;
recessing the plurality of fin structures exposed by the plurality of sacrificial gate structures;
forming epitaxial regions from the plurality of fin structures;
forming replacement gate structures; and
forming dielectric isolation structures between the epitaxial regions.

17. The method of claim 16, wherein forming the epitaxial regions comprises:
forming epitaxial emitter regions over the first well;
forming first epitaxial base regions over the first well;
forming second epitaxial base regions over the first well, wherein the first and second epitaxial regions are on opposite sides of the epitaxial emitter regions;
forming first epitaxial collector regions over the second well; and
forming second epitaxial collector regions over the third well.

18. The method of claim 17, wherein forming the dielectric isolation structures comprises:
forming a first metal gate structure between the first epitaxial collector regions and the first epitaxial base regions, and a second metal gate structure between the second epitaxial collector regions and the second epitaxial base regions.

19. The method of claim 18, wherein forming the dielectric isolation structures further comprises:
forming a third metal gate structure between the epitaxial emitter regions and the first epitaxial base regions; and
forming a fourth metal gate structure between the second epitaxial collector regions and the epitaxial emitter regions.

20. The method of claim 19, wherein a bottom surface of the cut metal structures is within the STI region.
